(19) United States
(12) Patent Application Publication
(10) Pub. No.: US 2004/0080013 A1
(43) Pub. Date: Apr. 29, 2004

(54) Chip-stack semiconductor device and manufacturing method of the same

(75) Inventors: Toshio Kimura, Kitakatsuragi-gun (JP); Yoshihisa Dotta, Nara-shi (JP)

Correspondence Address: NIXON & VANDERHYE, PC, 1100 N GLEBE ROAD, 8TH FLOOR, ARLINGTON, VA, 22201-4714, US

(73) Assignee: SHARP KABUSHIKI KAISHA, Osaka (JP)

(21) Appl. No.: 10/670,194

(22) Filed: Sep. 26, 2003

(30) Foreign Application Priority Data
Oct. 28, 2002 (JP) 2002-313528

(51) Int. Cl. H01L 29/00

(52) U.S. Cl. 257/499

(57) ABSTRACT

In a chip-stack semiconductor device including multiple semiconductor chips vertically stacked on top of each other, each of the semiconductor chips includes multiple through electrodes connected to each other in regions inside of electrode pads derived from a device region, and each of the through electrodes links a front surface to a back surface of the semiconductor chip. This arrangement provides a chip-stack semiconductor device which can prevent the increase in the size of the device and resolve the difficulty of stacking multiple semiconductor chips on top of each other, both of which are the problems associated with the provision of a number of through electrodes.

### FIELD OF THE INVENTION

The present invention relates to chip-stack semiconductor devices incorporating semiconductor chips with through electrodes vertically stacked on top of each other, for improved functionality, compactness, and reduced thickness, and a manufacturing method of the same.

### BACKGROUND OF THE INVENTION

CSP (Chip Size Package) semiconductor devices have been popularly used to meet the demand for compact electronics and automated manufacturing steps.

FIG. 30 shows the cross-sectional structure of a wire-bonded CSP semiconductor device 100 as an example. The wire-bonded CSP semiconductor device 100 has gold wires 103 extending from electrode pads 102 formed along the periphery of a semiconductor chip 101. Through the gold wires 103, the semiconductor chip 101 is electrically connected to an interposer substrate, or circuit board, 104. The wire-bonded CSP semiconductor device 100 has also external lead electrodes 105 formed on the back of the interposer substrate 104, via which electrodes 105 the interposer substrate 104 is connected to an external device (not shown in the figure).

The wire bonding by means of the gold wires 103 electrically connects the electrode pads 102 on the semiconductor chip 101 to the interposer substrate 104. The gold wires 103 add an extra height to the device 100. They also need be sealed by molding resin 106 for protection. These factors present difficulties in reducing the thickness of the wire-bonded CSP semiconductor device 100.

FCB (Flip Chip Bonding) semiconductor devices like the one shown in FIG. 31(a) and those with through electrodes like the one shown in FIG. 31(b) offer solutions to these problems. These types of CSP semiconductor devices eliminate the need for wires, thereby allowing for thinner devices.

In the FCB semiconductor device 200 in FIG. 31(a), a semiconductor chip 201 is electrically connected to contact pads 205 on an interposer substrate 204 via protrusion electrodes 203 formed on electrode pads 202. The semiconductor chip 201 is positioned so that its surface 206 on which circuitry is formed is opposite to the interposer substrate 204. Sealing resin 207 resides between the surface 206 and the interposer substrate 204 to provide protection to the semiconductor chip 201 and the connecting parts.

In the semiconductor device 210 in FIG. 31(b) where electrical connections are provided by means of through electrodes, protrusion electrodes 215 electrically connect through electrodes 212 formed on a semiconductor chip 211 to contact pads 214 formed on an interposer substrate 213. Sealing resin 216 may be injected for sealing between the semiconductor chip 211 and the interposer substrate 213 if necessary; when this is the case, circuitry is formed on the upper surface 217 of the semiconductor chip 211.

Japanese Published Unexamined Patent Application 10-223833 (Tokukaihei 10-223833/1998; published on Aug. 21, 1998), Japanese Patent 3186941 (issued on May 11, 2001), U.S. Pat. No. 6,184,060 (Date of patent: Feb. 6, 2001), and other recent documents disclose proposed multi-chip semiconductor devices in which the foregoing semiconductor device includes film carrier semiconductor modules (chips) which are stacked vertically on top of each other and connected electrically for greater packaging efficiency.

Referring to FIG. 32, a multi-chip semiconductor device 300 described in Tokukaihei 10-223833/1998 includes three chips 301a, 301b, 301c stacked sequentially upwards from bottom. Each chip 301a, 301b, 301c is principally made up of a silicon substrate 302 carrying integrated devices; wiring layers 303 connecting the integrated devices in a predetermined pattern; through electrodes (connection plugs) 306 provided inside through holes 305 extending through the silicon substrate 302 and an interlayer insulating film 304 for the wiring layers 303 to electrically connect the chips 301a, 301b to the chips 301b, 301c; and an opening insulating film 307. The through electrodes 306 provide external connection terminals for grounding and power and various signal supplies, and are formed in accordance with uses for each chip 301a, 301b, 301c. The back of the silicon substrate 302, except for the openings for the through electrodes 306, is covered with a back insulating film 308.

Through the wiring layers 303 on the chip 301a, 301b, 301c are there provided electrode pads 309 electrically connected to the metal plugs 306. The through electrode 306 for the chip 301a is connected to the through electrode 306 for the chip 301b via an electrode pad 309 and a solder bump 310; meanwhile, the through electrode 306 for the chip 301b is connected to the through electrode 306 for the semiconductor chip 301c via another electrode pad 309 and another solder bump 310.

Thus, the chips 301a, 301b, 301c are electrically connected with each other, offering a chip-stack semiconductor device.

In the conventional chip-stack semiconductor device, the terminal for the same signal is disposed at the same position on every chip, to provide electrical connections between the vertically stacked chips.

However, in the conventional chip-stack semiconductor device with through electrodes, the through holes were formed in the region outside of a device region. However, increase in the number of stacked semiconductor chips increases the number of through holes for through electrodes. In addition, since increase in the number of stacked chips causes no electrical actions of the semiconductor chips. This requires non-contact through electrodes merely for acting as intermediaries between the vertically stacked semiconductor chips.

As a result of this, the formation of through holes increases the periphery of the chip-stack semiconductor device, thus causing the difficulty in size reduction of a chip-stack semiconductor device.

### SUMMARY OF THE INVENTION

An object of the present invention is to offer a chip-stack semiconductor device which can prevent the increase in the size of the device and resolve the difficulty of stacking multiple semiconductor chips on top of each other, both of which are the problems associated with the provision of a number of through electrodes, and a manufacturing method of the chip-stack semiconductor device.

In order to achieve the above object, in the chip-stack semiconductor device of the present invention including multiple semiconductor chips vertically stacked on top of each other, and each of the semiconductor chips includes multiple through electrodes connected to each other in regions inside of electrode pads derived from a device region, and each of the through electrodes links a front surface to a back surface of the semiconductor chip.

That is, conventionally, through electrodes were provided in the periphery of the electrode pad, which is the region outside of the electrode pad, to contact upper and lower semiconductor chips via the through electrodes.

However, in this case, increase in the number of stacked semiconductor chips increased the number of through electrodes. This required a wide space for the through electrodes along the periphery of the semiconductor chip, causing the difficulty in size reduction of a chip-stack semiconductor device.

However, in the present invention, the multiple through electrodes are connected to each other in the region inside of the electrode pad, and each of the through electrodes links a front surface to a back surface of the semiconductor chip. Therefore, the region of the electrode pad is available for a space for the formation of the through electrodes.

This eliminates the need for a wide periphery of the semiconductor chip. Therefore, it is possible to alleviate the difficulty of maintaining a space for the through electrodes only with the periphery of the semiconductor chip and to reduce the size of the chip-stack semiconductor device. It is also possible to easily realize stacking of multiple semiconductor chips on top of each other.

Consequently, it is possible to offer the chip-stack semiconductor device which can prevent the increase in the size of the device and resolve the difficulty of stacking multiple semiconductor chips on top of each other, both of which are the problems associated with the provision of a number of through electrodes.

Further, in order to achieve the above object, a manufacturing method of a chip-stack semiconductor device of the present invention, includes:

semiconductor chip manufacturing step of forming semiconductor chips; and

semiconductor chip stacking step of stacking a plurality of the multiple semiconductor chip,

the semiconductor chip manufacturing step including the steps of:

(a) using a mask having an opening with a predetermined shape in a region inside of an electrode pad derived from a device region, forming a groove being made through the electrode pad and having a predetermined depth in the semiconductor chip;

(b) forming an insulating film on an inside wall of the groove;

(c) filling the groove with a conductive material; and

(d) forming the through electrode made of the conductive material linking a front surface to a back surface of the semiconductor chip by removing a back surface of the semiconductor chip partially in a thickness direction to expose the conductive material,

the steps (a)-(d) being carried out in this order.

According to the above invention, the manufacturing method of the chip-stack semiconductor device first includes the semiconductor chip manufacturing step of forming the semiconductor chip and the semiconductor chip stacking step of vertically stacking a plurality of the semiconductor chip on top of each other.

The semiconductor chip manufacturing step includes the following steps in the order presented:

the step of using a mask having an opening with a predetermined shape in a region inside of an electrode pad derived from a device region, forming a groove being made through the electrode pad and having a predetermined depth in the semiconductor chip;

the step of forming an insulating film on an inside wall of the groove;

the step of filling the groove with a conductive material; and

the step of forming the through electrode made of the conductive material linking a front surface to a back surface of the semiconductor chip by removing a back surface of the semiconductor chip partially in a thickness direction to expose the conductive material.

For example, in the case where the chip-stack semiconductor device is manufactured using the semiconductor chips each formed with the existing electrode pads, the manufacture of the chip-stack semiconductor device in the above steps enables easily forming the through electrodes in the region inside of the electrode pad.

Consequently, it is possible to offer a manufacturing method of the chip-stack semiconductor device which can prevent the increase in the size of the device and resolve the difficulty of stacking multiple semiconductor chips on top of each other, both of which are the problems associated with the provision of a number of through electrodes.

For a fuller understanding of the nature and advantages of the invention, reference should be made to the ensuing detailed description taken in conjunction with the accompanying drawings.

### BRIEF DESCRIPTION OF THE DRAWINGS

FIG. 1 is a view illustrating an embodiment of a chip-stack semiconductor device according to the present invention and is a cross-sectional view of the semiconductor device of FIGS. 2(a)-2(e) along line A-A.

FIGS. 2(a)-2(e) are plan views illustrating structures of semiconductor chips in a chip-stack semiconductor device.

FIG. 3(a) is a plan view illustrating a structure of a semiconductor chip used in the present embodiment, and FIG. 3(b) is a cross-sectional view magnifying a part of the semiconductor chip of FIG. 3(a) along line B-B.

FIGS. 4(a)-4(d) are cross-sectional views illustrating manufacturing steps for the through electrodes in the semiconductor chip.

FIGS. 5(a)-5(d) are cross-sectional views illustrating manufacturing steps for the through electrodes in the semiconductor chip, subsequent to the step in FIG. 4(d).

FIGS. 6(a)-6(d) are cross-sectional views illustrating manufacturing steps for the through electrodes in the semiconductor chip, subsequent to the step in FIG. 5(d).

FIGS. 7(a)-7(d) are cross-sectional views illustrating manufacturing steps for the through electrodes in the semiconductor chip, subsequent to the step in FIG. 6(d).

FIGS. 8(a)-8(d) are cross-sectional views illustrating manufacturing steps for the through electrodes in the semiconductor chip, subsequent to the step in FIG. 7(d).

FIG. 9(a) is a view illustrating a manufacturing step for the through electrodes in the semiconductor chip, subsequent to the step in FIG. 8(d) and is a cross-sectional view illustrating a semiconductor chip with gold bumps being formed on the through electrodes. FIG. 9(b) is a cross-sectional view illustrating a chip-stack semiconductor device offered by stacking the semiconductor chips of FIG. 9(a).

FIG. 10 is a view illustrating another embodiment of a chip-stack semiconductor device according to the present invention and is a cross-sectional view of the semiconductor device of FIG. 11(a)-11(e) along line C-C.

FIG. 11(a)-11(e) are plan views illustrating structures of semiconductor chips in the chip-stack semiconductor device of FIG. 10.

FIG. 12 is a cross-sectional view illustrating another embodiment of the chip-stack semiconductor device of FIG. 10.

FIGS. 13(a)-13(d) are cross-sectional views illustrating manufacturing steps for the semiconductor device of FIG. 10.

FIGS. 14(a)-14(d) are cross-sectional views illustrating manufacturing steps for the semiconductor device, subsequent to the step in FIG. 13(d).

FIGS. 15(a)-15(d) are cross-sectional views illustrating manufacturing steps for the semiconductor device, subsequent to the step in FIG. 14(d).

FIGS. 16(a)-16(d) are cross-sectional views illustrating manufacturing steps for the semiconductor device, subsequent to the step in FIG. 15(d).

FIGS. 17(a)-17(d) are cross-sectional views illustrating manufacturing steps for the semiconductor device, subsequent to the step in FIG. 16(d).

FIG. 18(a) is a view illustrating a manufacturing step for the through electrodes in the semiconductor chip, subsequent to the step in FIG. 17(d) and is a cross-sectional view illustrating a semiconductor chip with gold bumps being formed on the through electrodes. FIG. 18(b) is a cross-sectional view illustrating a chip-stack semiconductor device offered by stacking the semiconductor chips of FIG. 18(a).

FIGS. 19(a)-19(d) are cross-sectional views illustrating manufacturing steps for in the case where bumps are formed without providing a rearranged interconnect pattern, subsequent to the step in FIG. 16(b).

FIG. 20 is a cross-sectional view illustrating a semiconductor chip offered by forming bumps without providing a rearranged interconnect pattern.

FIG. 21 is a view illustrating another embodiment of a chip-stack semiconductor device according to the present invention and is a cross-sectional view of the semiconductor device of FIGS. 22(a)-22(e) along line D-D.

FIGS. 22(a)-22(e) are plan views illustrating structures of semiconductor chips in the chip-stack semiconductor device of FIG. 21.

FIG. 23 is a view illustrating further another embodiment of a chi-stack semiconductor device according to the present invention and is a cross-sectional view illustrating the chip-stack semiconductor device where the upper and lower semiconductor chips include through electrodes located at different positions, but electrically connected.

FIGS. 24(a)-24(d) are cross-sectional views illustrating manufacturing steps for the chip-stack semiconductor device in FIG. 23.

FIGS. 25(a)-25(d) are cross-sectional views illustrating manufacturing steps, subsequent to the step in FIG. 24(d).

FIGS. 26(a)-26(d) are cross-sectional views illustrating manufacturing steps, subsequent to the step in FIG. 25(d).

FIG. 27 is a cross-sectional view illustrating a semiconductor chip where conductors are formed on the back of a wafer, offered by the above manufacturing steps.

FIG. 28 is a cross-sectional view illustrating a semiconductor chip where conductors are formed on the front surface of a wafer.

FIGS. 29(a) and 29(b) are cross-sectional views illustrating manufacturing steps in the case where conductors are formed by electroless plating.

FIG. 30 is a cross-sectional view illustrating a conventional semiconductor device.

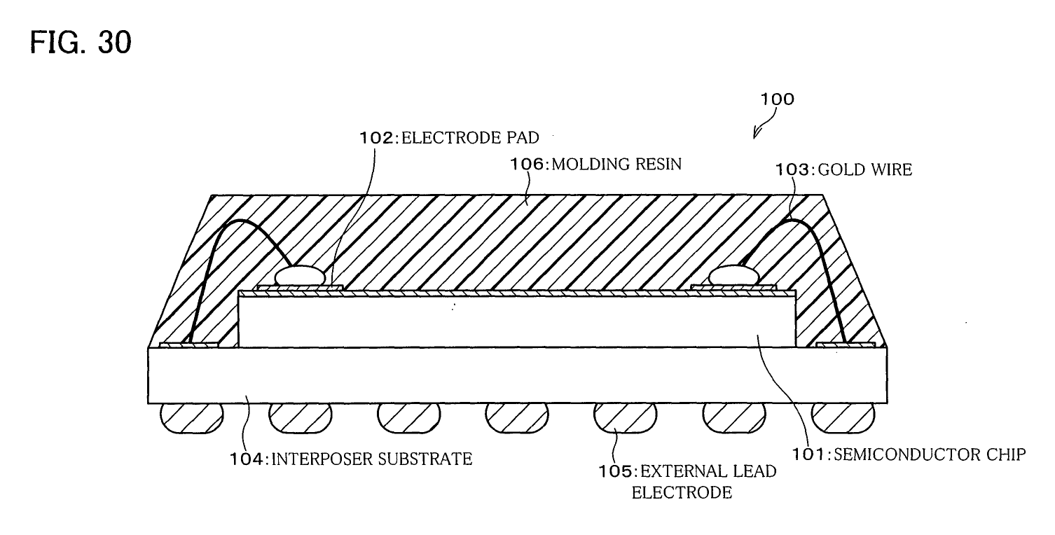

FIGS. 31(a), 31(b) are cross-sectional views illustrating another conventional semiconductor device.

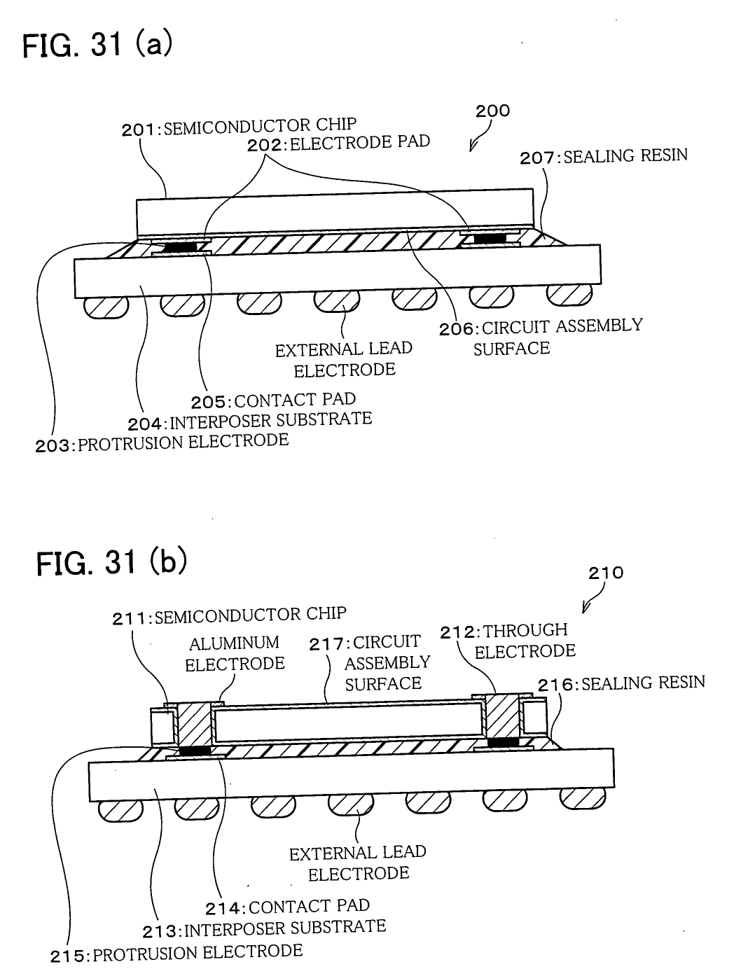

FIG. 32 is a cross-sectional view illustrating a conventional chip-stack semiconductor device.

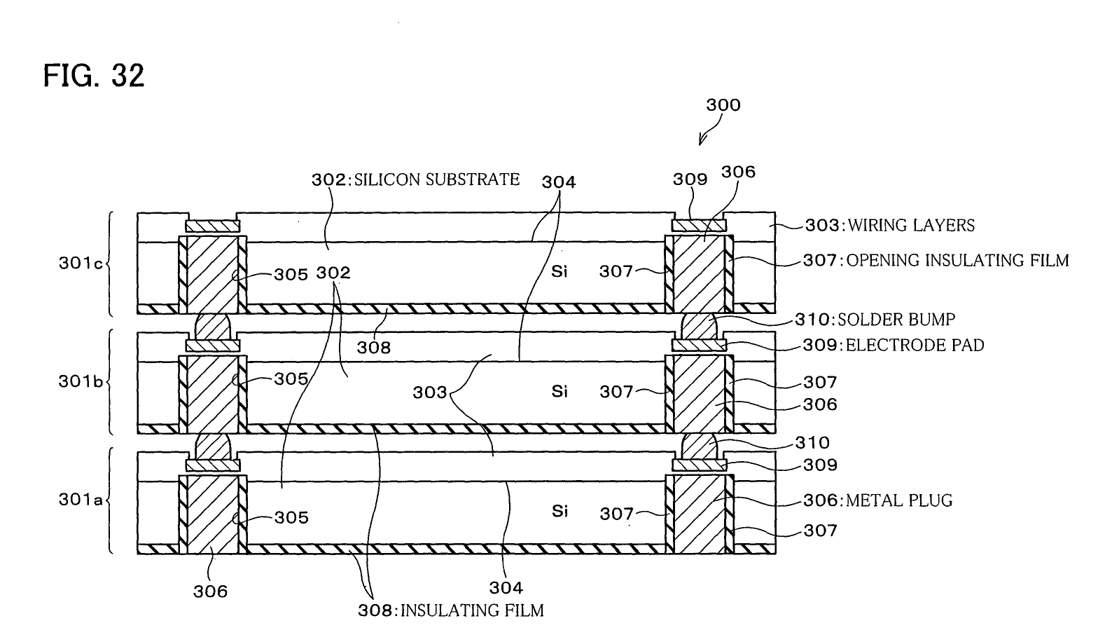

### DESCRIPTION OF THE EMBODIMENTS

[Embodiment 1]

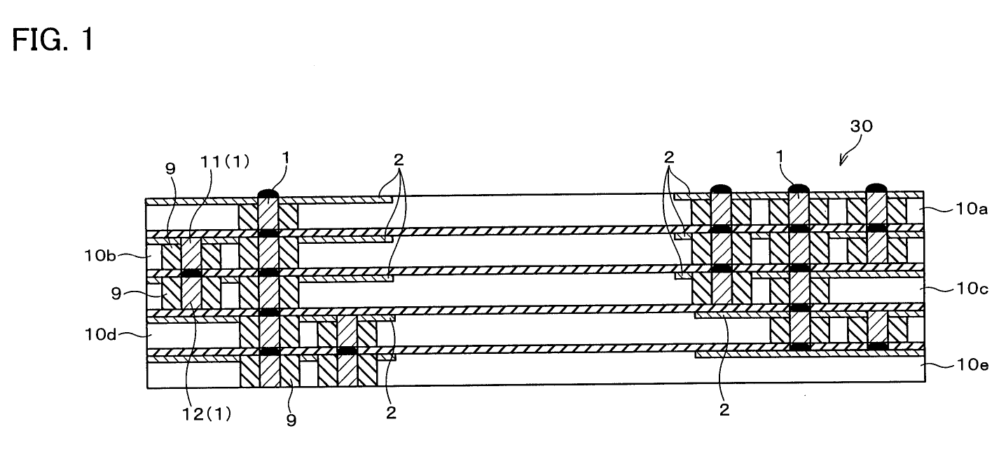

Referring to FIG. 1 through FIG. 9, the following will describe an embodiment according to the present invention.

As shown in FIG. 1, a chip-stack semiconductor device 30 of the present embodiment is composed of, for example, five semiconductor chips 10 sequentially stacked: a first semiconductor chip 10a, a second semiconductor chip 10b, a third semiconductor chip 10c, a fourth semiconductor chip 10d, and a fifth semiconductor chip 10e, from the top to the bottom. Note that, in the present embodiment, the five semiconductor chips 10 are stacked vertically on top of each other. However, the number of semiconductor chips is not necessarily limited to five. The semiconductor chip may take any number.

The chip-stack semiconductor device 30, in order to electrically connect the semiconductor chips 10, includes through electrodes 1 each linking a front surface to a back surface of a semiconductor chip 10, which will be described later, in one semiconductor chip 10. With this arrangement, for example, an electrode pad 2 formed on the front surface of the first semiconductor chip 10a at the top of the semiconductor chips 10 is electrically connected down to an electrode pad 2 formed on the front surface of the fifth semiconductor chip 10e at the bottom of the semiconductor chips 10. This provides electrical connections from the bottom surface of the fifth semiconductor chip 10e to an external substrate (not shown), for example, an interposer substrate.

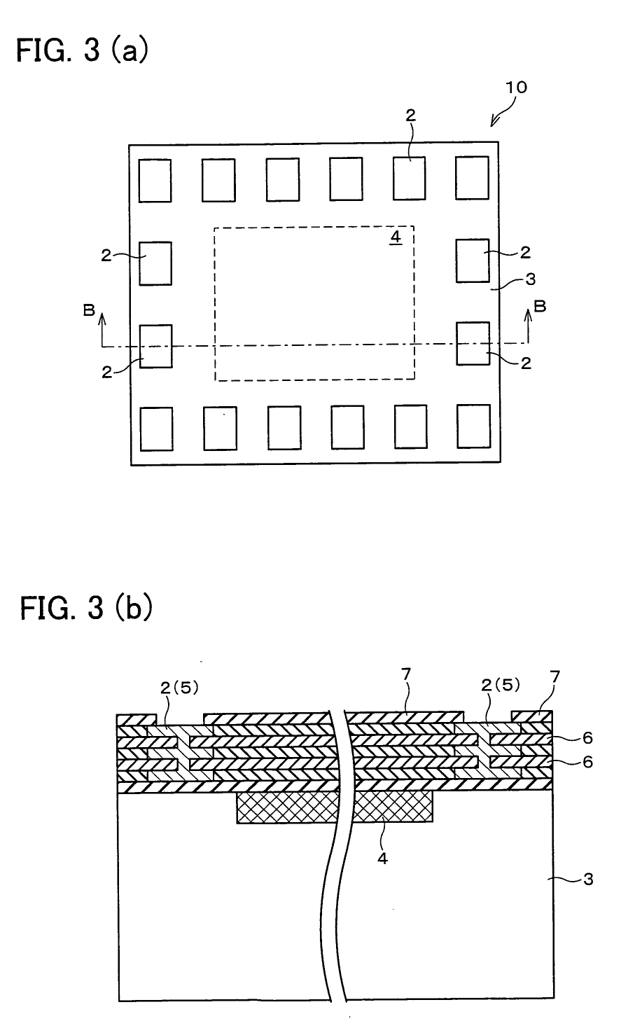

That is, the semiconductor chip 10, as shown in FIG. 3(a) and FIG. 3(b), principally has a device region 4 at the substantially central position of a silicon (Si) substrate 3 which is constituted by a semiconductor wafer From the device region 4, a plurality of interconnect patterns having three layers, which are made of aluminum (Al) or copper (Cu), extend outwardly in a state of being insulated by interlayer insulating films 6.

The tips of the interconnect patterns extend to electrode pads 2 provided along the periphery of the semiconductor chip 10. The electrode pads 2 expose from a passivation film 7 provided on the front surface of the semiconductor chip 10. The electrode pads 2 are provided along the periphery of the semiconductor chip 10 so as to surround the device region 4. The electrode pads 2 serve as external lead electrodes. Note that, the interconnect patterns having three layers are given in the above description of the present embodiment. The interconnect pattern having one layer or other plural number of layers may also be adopted.

More specifically, in the semiconductor chip 10, numerous fine lines extend from the device region 4 as an interconnect pattern. The electrode pad 2 refers to the relatively large electrode terminal disposed on the tip of an interconnect pattern along the periphery of the semiconductor chip 10 to provide an external electrical input/output within the interconnect pattern, and the electrode pad 2 exposes on the front surface of the semiconductor chip 10.

Further, the device region 4 refers to the place where the semiconductor elements electrically operate and to the part where switching is performed. Specifically, the device region 4 is the part of source, gate, and drain.

The chip-stack semiconductor device 30 of the present embodiment includes five stacked semiconductor chips 10 each having the aforementioned principal structure.

In the chip-stack semiconductor device 30, to vertically stack the semiconductor chips 10 on top of each other, the through electrodes 1 must be formed. Conventionally, through holes are formed along the periphery of the electrode pad 2 to form the through electrodes 1. However, increase in the number of stacked semiconductor chips 10 increases the number of through holes for the through electrodes 1. In addition, increase in the number of stacked semiconductor chips 10 needs non-contact through electrodes 19 merely for acting as intermediaries between the vertically stacked semiconductor chips 10. That is, for example, in a comparison between three stacked semiconductor chips and five stacked semiconductor chips, signals do not always come back to the same place, and the signals may come back to the different place. This increases the number of through electrodes 1.

This increases the peripheral area of the semiconductor chip 10 to form the through holes, thus causing the difficulty in size reduction of the chip-stack semiconductor device.

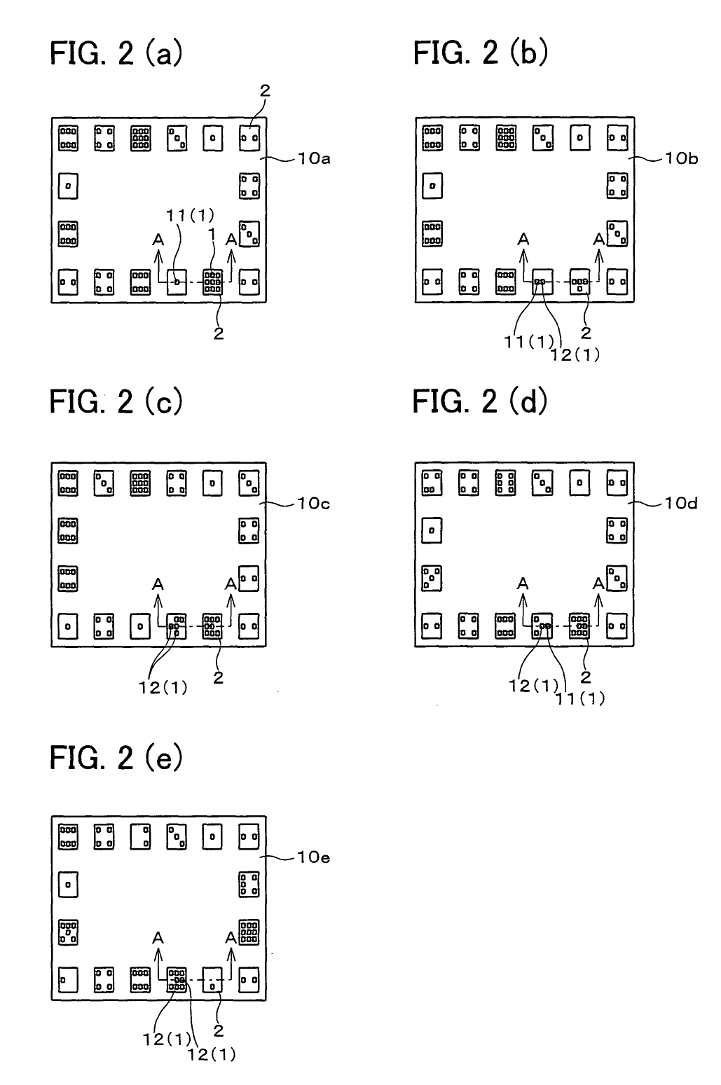

To solve the problem, in the present embodiment, as shown in FIG. 1 and FIGS. 2(a)-2(e), the through electrodes 1 are formed in regions inside of the electrode pads 2.

In the chip-stack semiconductor device 30, the leftmost through electrode 1 in FIG. 1 is connected to the electrode pad 2 of the second semiconductor chip 10b in order to provide connections between the second semiconductor chip 10b and the third semiconductor chip 10c. The through electrode 1 of the third semiconductor chip 10c is insulated from the electrode pad 2 of the third semiconductor chip 10c by an insulating film 9.

In the present embodiment, some of the through electrodes 1 connected to the electrode pads 2 are referred to as contact through electrodes 11, and the rest not connected to the electrode pads 7 is referred to as non-contact through electrodes 12.

Therefore, on the second left through electrodes 1 of FIG. 1, the through electrode 1 in the first semiconductor chip 10a is the contact through electrode 11, and the through electrodes 1 in the second semiconductor chip 10b through the fifth semiconductor chip 10e are the non-contact through electrodes 12. That is, the non-contact through electrodes 12, as described previously, acts as intermediaries between the vertically stacked semiconductor chips 10.

In the chip-stack semiconductor device 30 of the present embodiment, attention is now focused to the left electrode pad 2 in the second top second semiconductor chip 10b of FIG. 1. This electrode pad 2 is one for picking up one signal from the device region 4 in the second semiconductor chip 10b to connect it to the lower third semiconductor chip 10c, and the non-contact through electrode 12, the second left through electrode 1 in FIG. 1, is formed in regions inside of the electrode pad 2.

In other words, in the present embodiment, in a region inside of the electrode pad 2 for running a certain signal are there formed non-contact through electrodes 12 for running a different signal.

In the present embodiment, as shown in FIG. 2(a) through FIG. 2(e), in regions inside of the electrode pads 2 are there formed one through nine through electrodes 1, for example. However, the number of through electrodes 1 is not limited to this, and many more number of through electrodes 1 can be formed. Thus, in the chip-stack semiconductor device 30 of the present embodiment, in regions inside of the electrode pads 2 are there formed through electrodes 1. In addition, the through electrodes 1 in regions inside of the electrode pads 2 may be either the contact through electrodes 11 or the non-contact through electrodes 12.

Note that, the description assumes that each of the initial semiconductor chips 10 is a semiconductor chip where the electrodes 1 have not been formed yet under the electrode pad 2 in the present embodiment. However, the present invention is not necessarily limited to this. It may be a semiconductor chip where the electrodes 1 have been already formed under the electrode pad 2. This is because additional through electrodes 1 can be formed in a free region of the electrode pad 2.

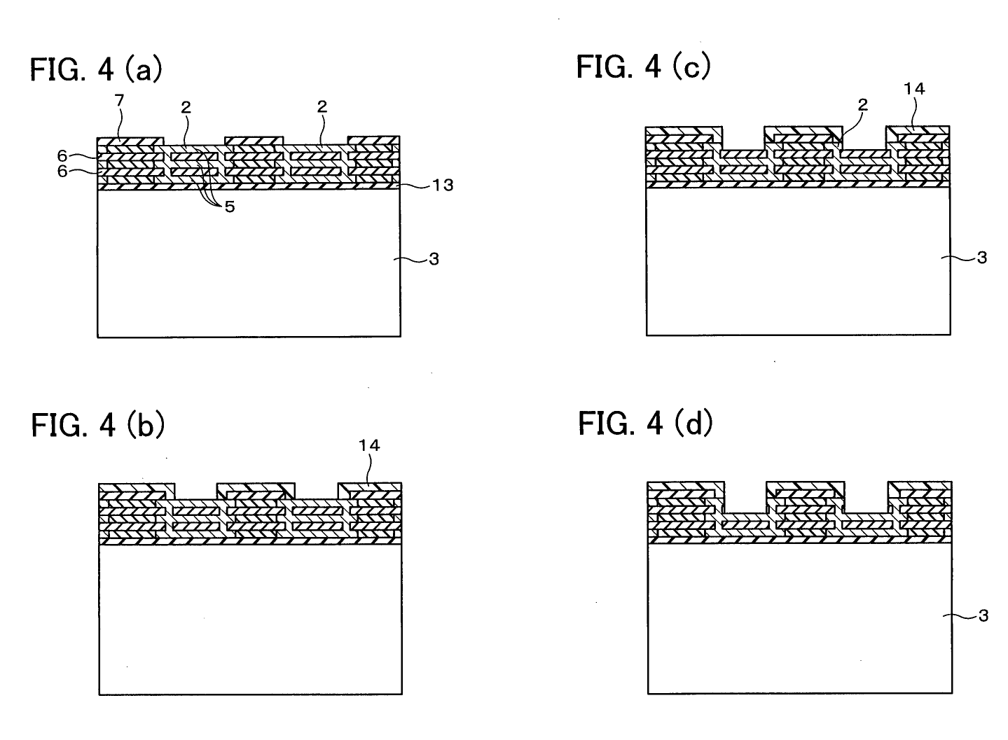

Referring to FIG. 4 through FIG. 10, the following will describe a method for simultaneously forming the contact through electrodes 11 and the non-contact through electrodes 12, both of which are the through electrodes 1, to the electrode pad 2 of the above-arranged semiconductor chip 10.

For example, as shown in FIG. 4(a), along the periphery of the semiconductor chip 10, the electrode pads 2 exposed from the surficial passivation film 7 are provided at two places. The size of the electrode pad 2 is 70 μm per side, for example.

Under the electrode pad 2, interconnect patterns 5 having two layers are formed through the interlayer insulating films 6. That is, the interconnect patterns 5 are made up of three layers among which the topmost interconnect pattern 5 is the electrode pad 2. Under the bottommost interconnect pattern 5, an interlayer film 13 is provided. Under the interlayer film 13 exists a silicon (Si) substrate 3. The interconnect pattern 5, which is made of a metal, for example, is wiring for directly feeding an electric current. Usually, the interconnect pattern 5 is made of a metal such as 99% aluminum (Al) and 1% silicon (Si), 99% aluminum (Al) and 1% copper (Cu), aluminum (Al) and palladium (Pd), or only copper (Cu). Note that, any type of metal may be adopted for the present invention.

In preparation for generating through holes for the formation of the through electrodes 1 in the electrode pad 2, as shown in FIG. 4(b), a resist 14 is applied to the entire wafer. Then, using a reduction projection aligner for the formation of through patterns, an opening for through hole pattern having 10 μm per side, for example, is made at one to nine places at the maximum in the region inside of the electrode pad 2 to expose the electrode pad 2 to light. Note that, for ease of explanation, the description assumes that one through hole is formed in each of the electrode pads 2.

The reduction projection aligner, which is generally called as “stepper”, is essential to the manufacture semiconductors, as a device for facilitating fine pattern fabrication. The reduction projection aligner enables fine patterning using a mask pattern reduced in size, not an actual mask pattern size. That is, although it is difficult to form a mask pattern of 1 μm for the use of the actual mask pattern size, it is possible to form a pattern of 1 μm using a mask pattern of 5 μm by a 1:5 stepper.

Moving on to FIG. 4(c), the part that has been exposed to light of the electrode pad 2 made of aluminum-silicon (Al—Si) or aluminum-copper (Al—Cu) wire is dry etched. Dry etching is a method using vapor-phase to solid phase interface reaction with gas, plasma, or ion of etching methods of fabricating the shape of a material layer and a thin film by means of chemical reactions. Absorption of etching species to the surface of a material that will be etched causes chemical reactions, and etching progresses by disposing and removing an outer part of a product separated from the surface of the material. This method is called dry etching in contrast to wet etching using a chemical solution.

Next, immediately it is followed by treatment for corrosion proof to prevent erosion to occur. Specifically, polymer removal and water washing are implemented. Subsequently, the interlayer insulating film 6 is dry etched. To facilitate successive etching of different film materials and achieve a minimum level of exposure to air, the step is preferably implemented using a multi-chamber dry etcher; otherwise, a single chamber must be used to accommodate an atmosphere of different gases, and especially, metal will erode due to excessive exposure to air.

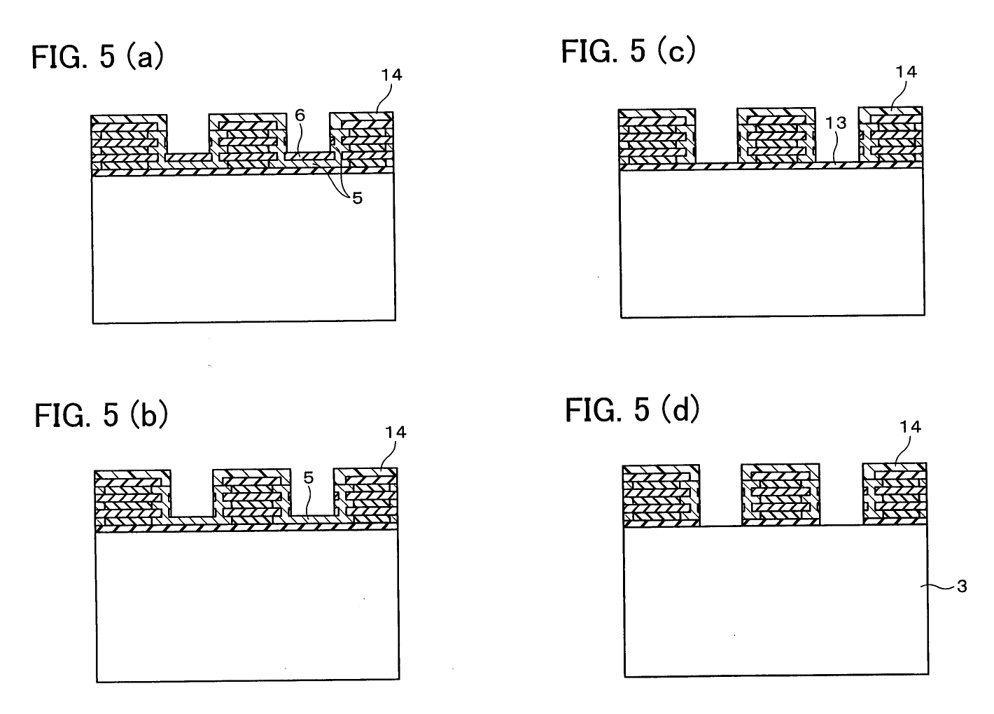

Next, as shown in FIG. 5(a) though FIG. 5(d), the above step is further repeated for interconnect patterns 5 of two layers, and the interlayer film 13 is etched down to the upper surface of the silicon (Si) substrate 3.

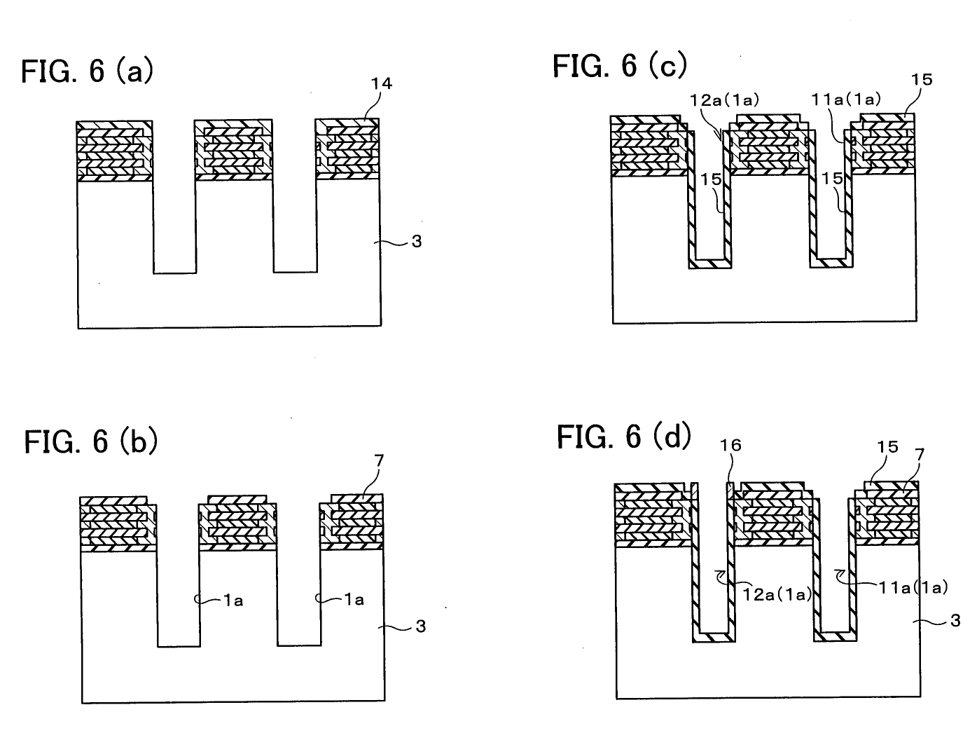

Moving on to FIG. 6(a), the silicon (Si) substrate 3 is etched by another dry etcher for silicon (Si) deep etching. At this moment, the silicon (Si) substrate 3 is etched down to, for example, 50 μm to 70 μm in depth, and the etching is completed halfway of the thickness of the silicon (Si) substrate 3.

Next, as shown in FIG. 6(b), the resist 14 that has been applied to the upper surface of the passivation film 7 is removed. Then, as shown in FIG. 6(c), a side wall insulating film 15 is grown using an insulating film growing facility along the wall surface of a contact through electrode through hole 11a, which is the through hole 1a for the contact through electrode 11, and a non-contact through electrode through hole 12a, which is the through hole 1a for the non-contact through electrode 12. In the present embodiment, to form the side wall insulating film 15 on the inside walls of the deep holes, a TEOS (tetraethylorthosilicate) oxide film is formed by CVD (Chemical Vapor Deposition). This time, the side wall insulating film 15 was formed with a thickness of, for example, about 1 μm on the inside walls. The TEOS oxide film refers to the oxide film formed on silicon (Si) using TEOS which is a liquid source used in CVD of silicon dioxide (SiO₂).

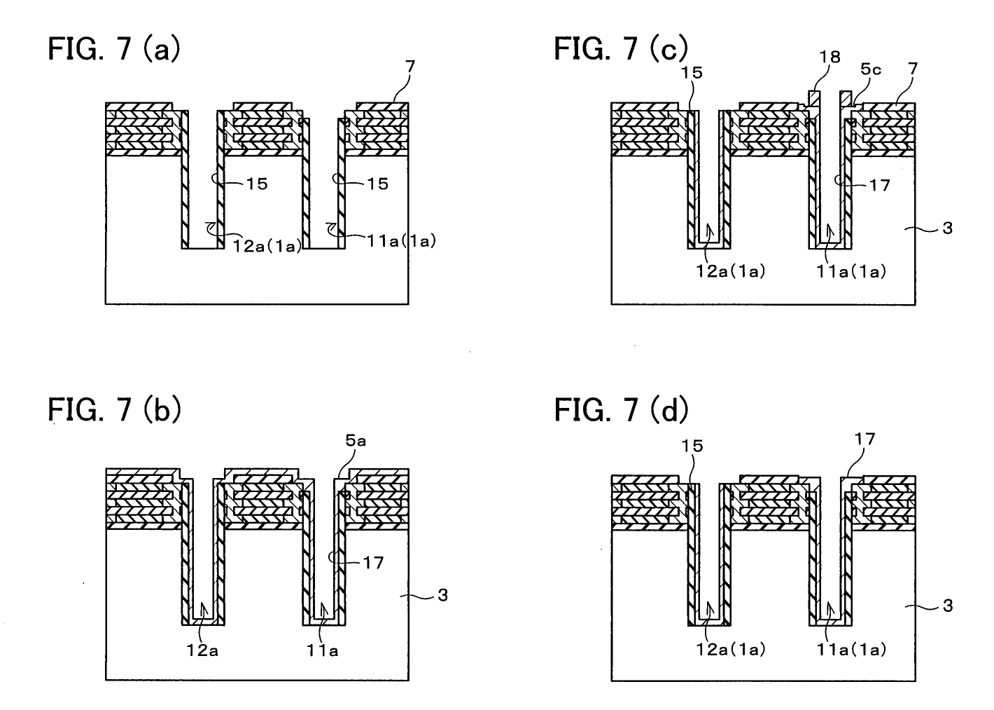

The side wall insulating film 15 grows also on the wafer surface. This must be removed by etch-back using a dry etcher. The side wall insulating film 15 should be retained in the side wall surface for the non-contact through electrode through hole 12a. As shown in FIG. 6(d), a resist 16 is applied, patterned using a reduction projection aligner, and covered. Thereafter, as shown in FIG. 7(a), the side wall insulating film 15 is etched away from the surface by Reactive Ion Etching (RIE). Further, the resist 16 is removed. Note that, RIE is an etch step whereby gas is made into a plasma state by an electric or magnetic field in a chamber (chemical reaction chamber) and a directional reactive ion species is used. Sputtering which progresses simultaneously with chemical reactions facilitates the formation of vertical cross-sectional shapes free from side etching, and is suitable for fine pattern fabrication.

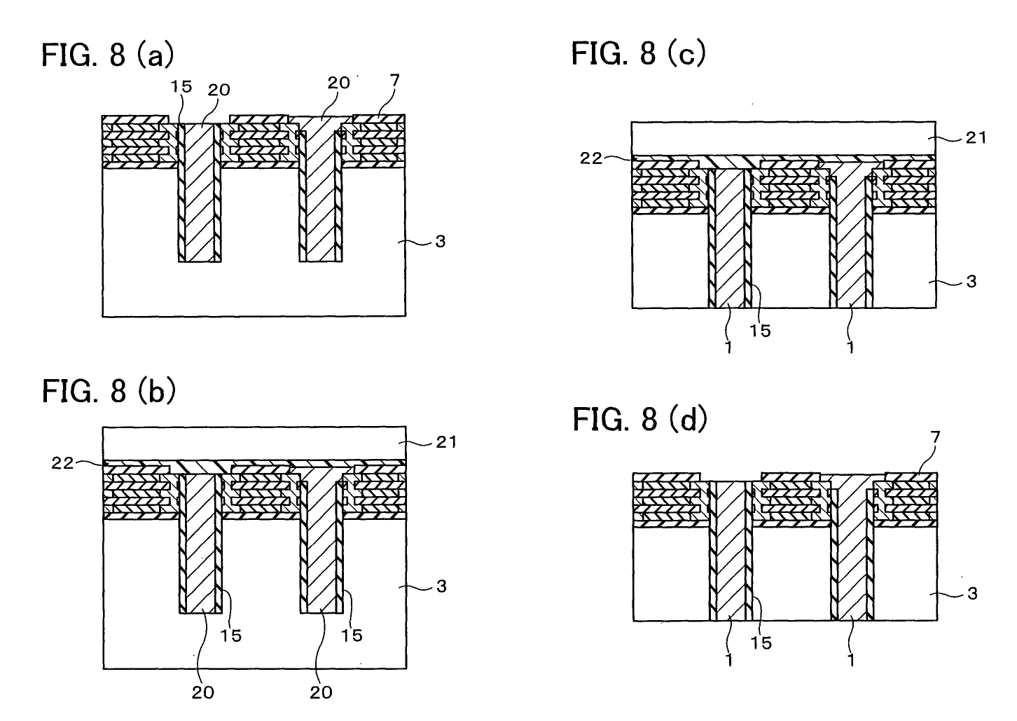

Referring now to FIG. 7(b), a metal film 17 as a seed layer is provided by sputtering, and as shown in FIG. 7(c), a resist 18 is applied. As shown in FIG. 7(d), the resist 18 is etched away except from the necessary parts, i.e. the inside of the contact through electrode through hole 11a and the non-contact through electrode through hole 12a, and a rearranged interconnect pattern 5a at the top parts of the wafer. Thereafter, as shown in FIG. 8(a), a conductor 20 is grown by an electroless plating technique.

Subsequently, as shown in FIG. 8(b), a support board 21 is attached to the wafer surface using a UV adhesive sheet, and the back of the silicon (Si) substrate 3 is polished, as shown in FIG. 8(c). The through electrodes 1 are exposed on the back of the wafer as a result of the polishing, and the support board 21 is removed, as shown in FIG. 8(d).

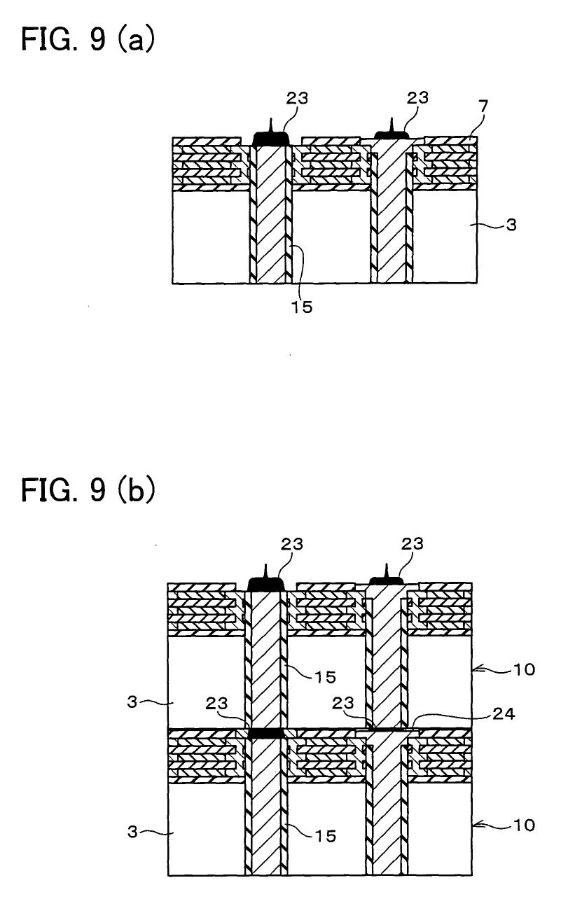

Next, as shown in FIG. 9(a), the bumps 23 made of, for example, gold wire bump, are formed on the grown conductors 20, and as shown in FIG. 9(b), the semiconductor chips 10 are contacted with each other through a conductive sheet 24, which completes the manufacture.

Note that, in the example above, gold wire bumps are used for the formation of the bumps 23. Therefore, since the bumps 23 are surrounded by aluminum-silicon (Al—Si) or aluminum-copper (Al—Cu) conductor 20, the bump 23 at the place where the non-contact through electrode through hole 12a is provided must be formed carefully so as not to short out with the conductor 20.

Thus, the chip-stack semiconductor device 30 of the present embodiment includes the multiple through electrodes 1 connected to each other in the region inside of the electrode pad 2, and each of the through electrodes 1 links a front surface to a back surface of the semiconductor chip 10. Therefore, the region of the electrode pad 2 is available for a space for the formation of the through electrodes 1.

This eliminates the need for a wide periphery of the semiconductor chip 10. Therefore, it is possible to alleviate the difficulty of maintaining a space for the through electrodes only with the periphery of the semiconductor chip 10 and to reduce the size of the chip-stack semiconductor device 30. It is also possible to easily realize stacking of multiple semiconductor chips on top of each other.

Consequently, it is possible to offer the chip-stack semiconductor device 30 which can prevent the increase in the size of the device and resolve the difficulty of stacking multiple semiconductor chips on top of each other, both of which are the problems associated with the provision of a number of through electrodes 1.

Further, in the chip-stack semiconductor device 30 of the present embodiment, since the electrode pads 2 are provided along the periphery of each of the semiconductor chips 8 so as to surround the device region 4, the device region 4 does not interfere with forming the through electrodes 1.

Still further, in the chip-stack semiconductor device 30 of the present embodiment, at least one type of the through electrodes 1 is the contact through electrodes 11 electrically connected to the electrode pad 2.

This makes it possible to form the contact through electrode 11 which is connected to a typical device region 4.

In addition, in the chip-stack semiconductor device 30 of the present embodiment, at least one type of the through electrodes 1 is the non-contact through electrodes 12 not electrically connected to the electrode pad 2. Therefore, the non-contact through electrodes 12 not connected to the device region 4 are provided merely for providing electrical paths though the semiconductor chips 10 as the through electrodes 1. Therefore, the heat generated in the semiconductor chip 10 can be discharged outside via the non-contact through electrodes 12 or can be guided to the semiconductor chip 10 in the lower layer in such a manner that the non-contact through electrodes 12 are connected to the contact through electrodes 11 of the semiconductor chip 10 in the upper layer.

Further, in the chip-stack semiconductor device 30 of the present embodiment, since the through electrodes 1 in the semiconductor chips 10 are connected to each other via the bumps 23 so that the semiconductor chips 10 are stacked on top of each other, it is possible to easily perform the stacking step.

Still further, a manufacturing method of the chip-stack semiconductor device 30 of the present embodiment first includes semiconductor chip manufacturing step of forming the semiconductor chip 10 and semiconductor chip stacking step of vertically stacking a plurality of the semiconductor chip 10 on top of each other.

The semiconductor chip manufacturing step includes the following steps in the order presented: the step of forming the through hole 1a that is a groove being made through the electrode pad 2 and having a predetermined depth in the semiconductor chip 10, using the resist 14 that is a mask having an opening with a predetermined shape, in the region inside of the electrode pad 2 derived from the device region 4; the step of forming the side wall insulating film 15 as an insulating film on the inside wall of the through hole 1a; the step of filling the through hole 1a with the conductor 20 as conductive material; and the step of forming the through electrode 1 made of the conductive material linking a front surface to a back surface of the semiconductor chip 10 by removing a back surface of the semiconductor chip 10 partially in a thickness direction to expose the conductive material.

For example, in the case where the chip-stack semiconductor device 30 is manufactured using the semiconductor chips 10 each formed with the existing electrode pads 2, the manufacture of the chip-stack semiconductor device 30 in the above steps enables easily forming the through electrodes 1 in the region inside of the electrode pad 2.

Consequently, it is possible to offer a manufacturing method of the chip-stack semiconductor device 30 which can prevent the increase in the size of the device and resolve the difficulty of stacking multiple semiconductor chips on top of each other, both of which are the problems associated with the provision of a number of through electrodes 1.

The manufacturing method of the chip-stack semiconductor device 30 of the present embodiment further includes, between the step of forming the side wall insulating film 15 on the inside wall of the through hole 1a and the step of filling the through hole 1a with the conductive material in the semiconductor chip manufacturing step, the step of removing the side wall insulating film 15 formed on the inside wall of the through hole 1a in the same layer as the electrode pad 2.

This makes it possible to easily form the non-contact through electrode 12.

In the manufacturing method of the chip-stack semiconductor device 30 of the present embodiment, in the step of forming the through hole 1a being made through the electrode pad 2 and having a predetermined depth in the semiconductor chip 10 in the semiconductor chip manufacturing step, the multiple through holes 1 are formed in the region inside of the electrode pad 2.

This makes it possible to form the multiple contact through electrodes 11 and non-contact through electrodes 12 in the region inside of one electrode pad 2.

[Embodiment 2]

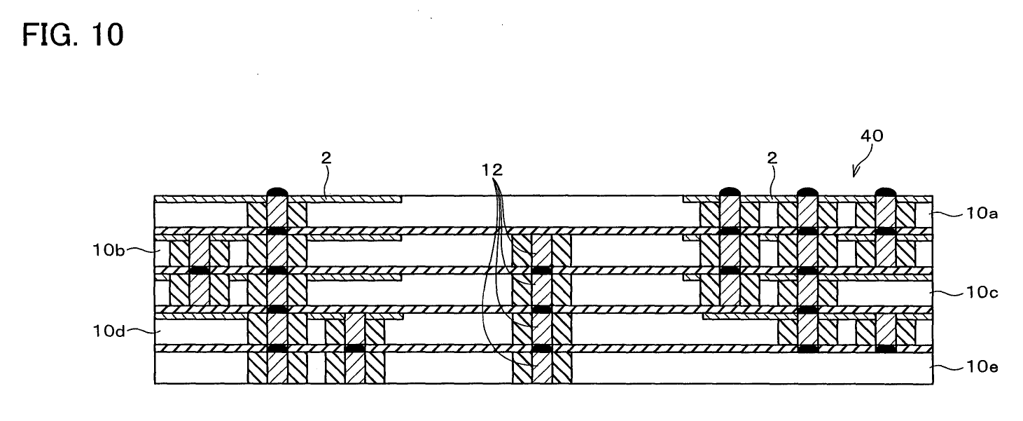

The following will describe another embodiment of the present invention with reference to FIG. 10 through FIG. 20. For convenience, members of the present embodiment that have the same arrangement and function as members of embodiment 1, and that are mentioned in that embodiment are indicated by the same reference numerals and description thereof is omitted.

The present embodiment will describe a case where the through electrode 1 is further provided in the regions outside of the electrode pad 2.

For example, since the increase in the number of stacked semiconductor chips 10 in the chip-stack semiconductor device increases the amount of heat generated in the semiconductor chips 10, the heat generated in the semiconductor chips 10 is preferably discharged down the chip-stack semiconductor device. In such a case or the like, the semiconductor chips do not perform electrical actions. This requires the non-contact through electrodes 12 merely for acting as intermediaries between the vertically stacked semiconductor chips 10.

In addition, electrical connections may be further needed among the semiconductor chips 10 in intermediate layers of the chip-stack semiconductor device.

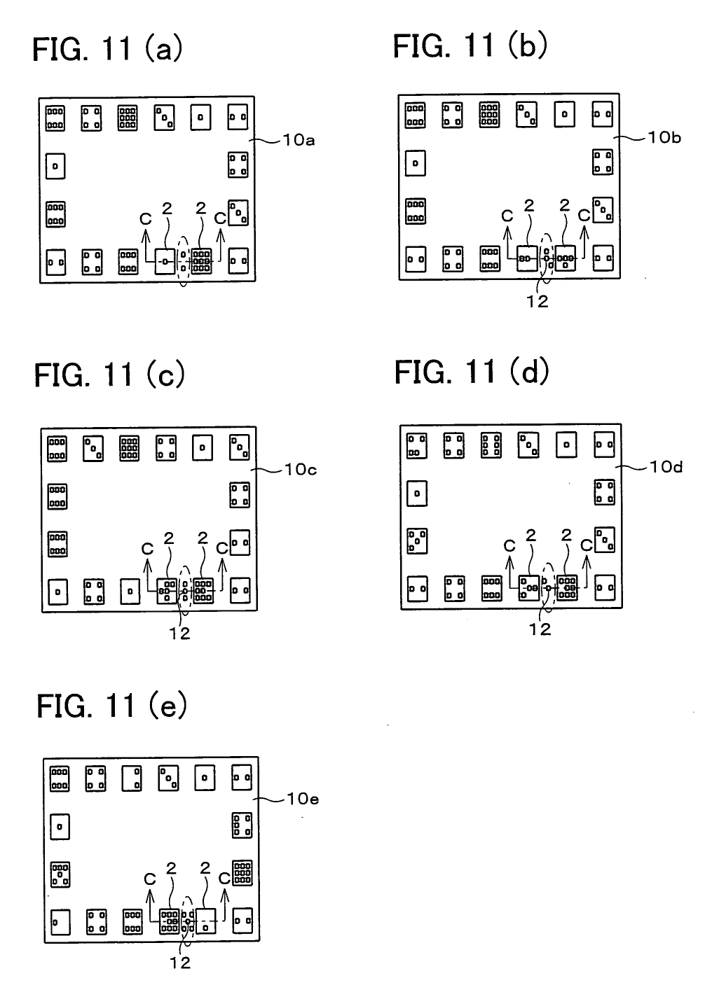

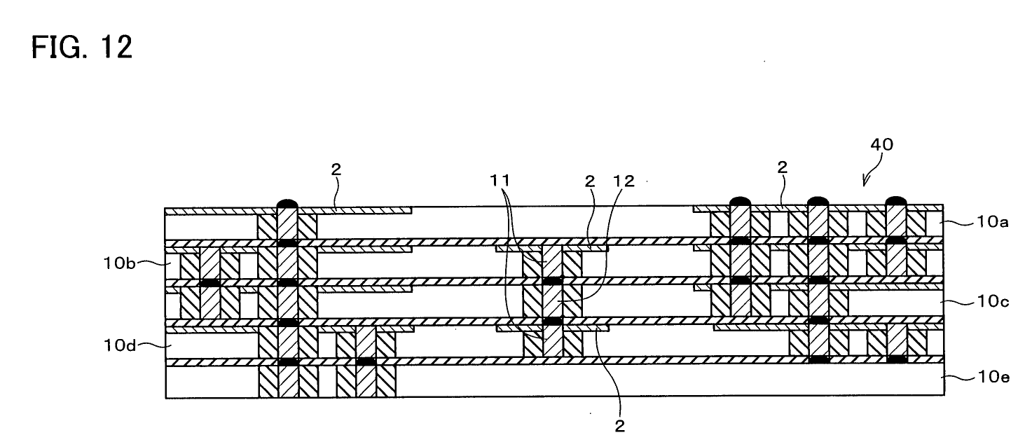

In view of this, the chip-stack semiconductor device 40 of the present embodiment, as shown in FIG. 10 and FIG. 11(a) through FIG. 11(e), includes the non-contact through electrodes 12 provided between the electrode pads 2, connecting the second semiconductor chip 10b, the third semiconductor chip 10c, the fourth semiconductor chip 10d, and the fifth semiconductor chip 10e. As shown in FIG. 12, between the existing electrode pads 2 (provided on the left and right sides in FIG. 10), it is possible to provide the contact through electrodes 11 in the second semiconductor chip 10b and the fourth semiconductor chip 10d and the non-contact through electrodes 12 in the third semiconductor chip 10c. In this case, for the formation of the contact through electrodes 11 in the second semiconductor chip 10b and the fourth semiconductor chip 10d, the electrode pads 2 must be newly formed.

That is, in additionally forming the through electrodes 1, the through electrodes 1 may no longer be formed in the region inside of the electrode pad 2 when a number of through electrodes 1 have already been formed in the region inside of the electrode pad 2. In such a case, the present embodiment offers a method of forming the through electrodes 1 in the regions outside of the electrode pad 2.

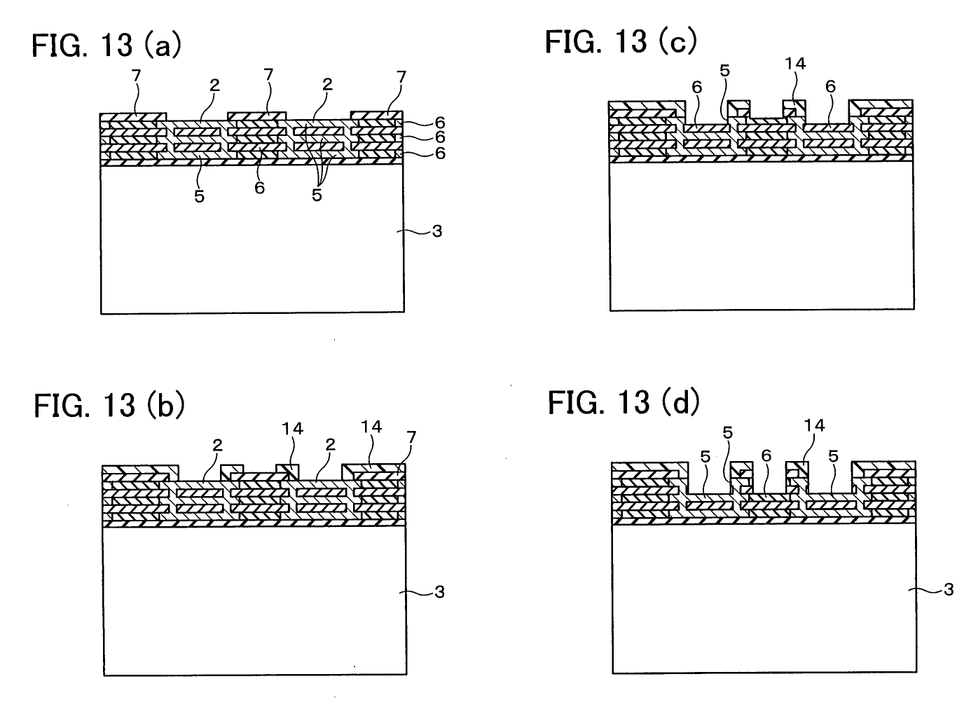

Referring to FIG. 13 through FIG. 19, the following will describe a method for forming through electrodes in the electrode pad 2 as well as forming the non-contact through electrodes 12 or the contact through electrodes 11 between the electrode pads 2, in forming the non-contact through electrodes 12 between the electrodes pads 2 in the above-arranged semiconductor chip 10. Note that, the steps in the present embodiment proceed in the same steps in embodiment 1, and detail description of the steps is omitted.

Also in the present embodiment, as shown in FIG. 13(a), along the periphery of the existing semiconductor chip 10, the electrode pads 2 exposed from the surficial passivation film 7 are provided at two places. That is, FIG. 13(a) is the same as FIG. 4(a) of embodiment 1.

In the present embodiment, the through electrodes 1 are also provided between the electrode pads 2. That is, the interlayer insulating films 6 exist with no other components such as interconnect patterns 5 under the region between the electrode pads 2. Therefore, the region between the electrode pads 2 can be maintained as a space for opening a non-contact through electrode through hole.

A resist 14 is applied to the entire wafer. Then, as shown in FIG. 13(b), using a reduction projection aligner for the formation of through patterns, openings for through hole pattern each having 10 μm per side, for example, are made in the region inside of the electrode pads 2 and in the region between the electrode pads 2 to expose the electrode pads 2 and the region between the electrode pads 2 to light.

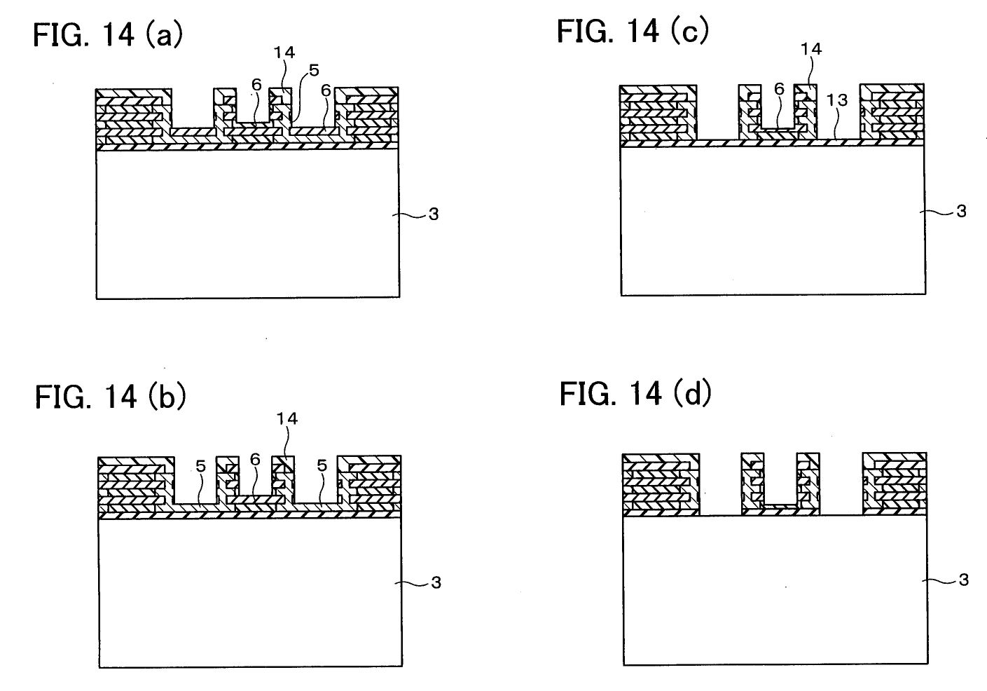

Next, as shown in FIG. 13(c), FIG. 13(d), and FIG. 14(a) through FIG. 14(d), by the same etching method as that in embodiment 1, the interconnect patterns 5 and the interlayer insulating films 6 are etched. At this moment, an etching rate of the interlayer insulating film 6, i.e. a speed at which the interlayer insulating film 6 is etched is extremely slow in the step of metal etching. Therefore, it takes longer to etch the region between the electrode pads 2 than the region of the electrode pad 2.

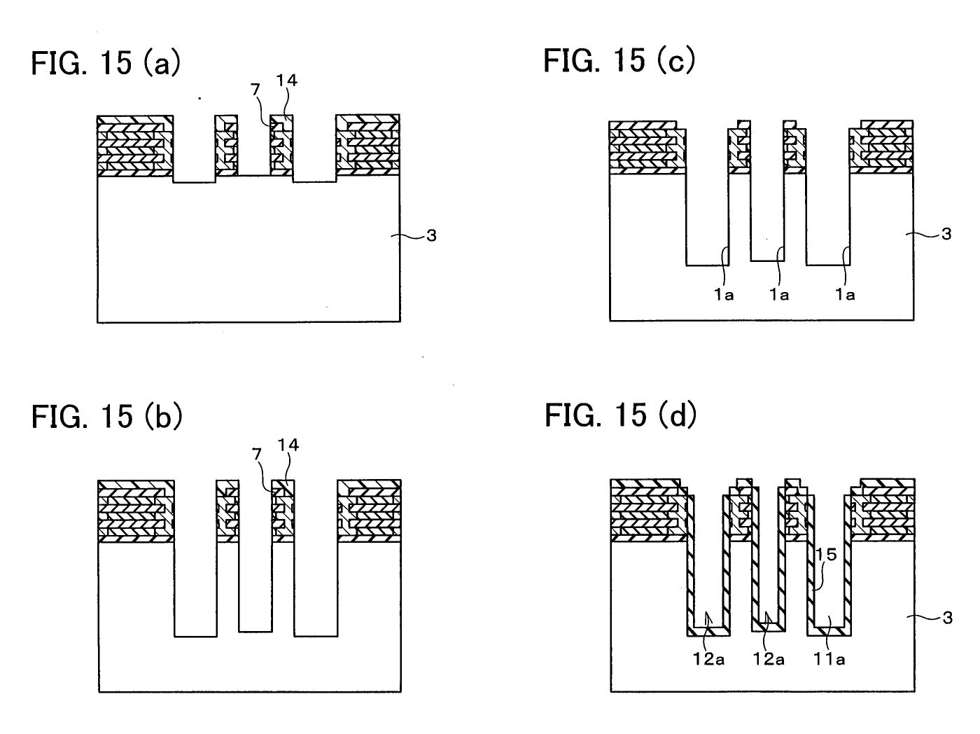

Then, as shown in FIG. 15(a), a residual insulating film in the interlayer insulating film 6, which remains in the final step of etching, is etched. At this moment, the silicon (Si) substrate 3 is over-etched about 1 micrometer in depth. However, this value is not a problem because it is followed by etching the silicon (Si) substrate 3 down to 50 μm to 70 μm in depth, as shown in FIG. 15(b).

Next, as shown in FIG. 15(b) through FIG. 18(a), the same steps as those shown in FIG. 6(b) through FIG. 9(a) in embodiment 1 are carried out.

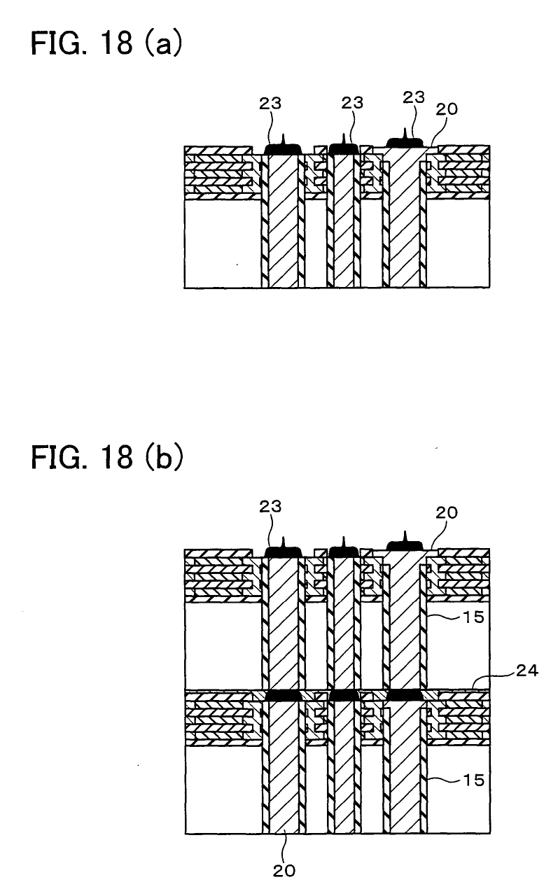

Then, as shown in FIG. 18(b), the semiconductor chips 10 formed in such a manner are contacted with each other through the conductive sheet 24, which completes the manufacture of the chip-stack semiconductor device 40.

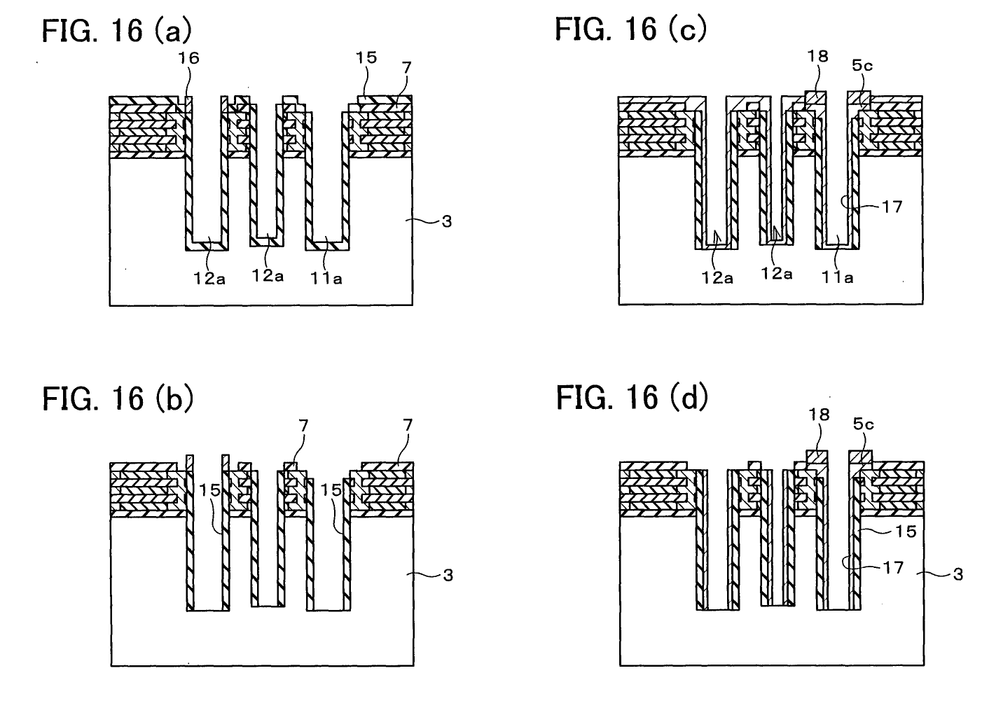

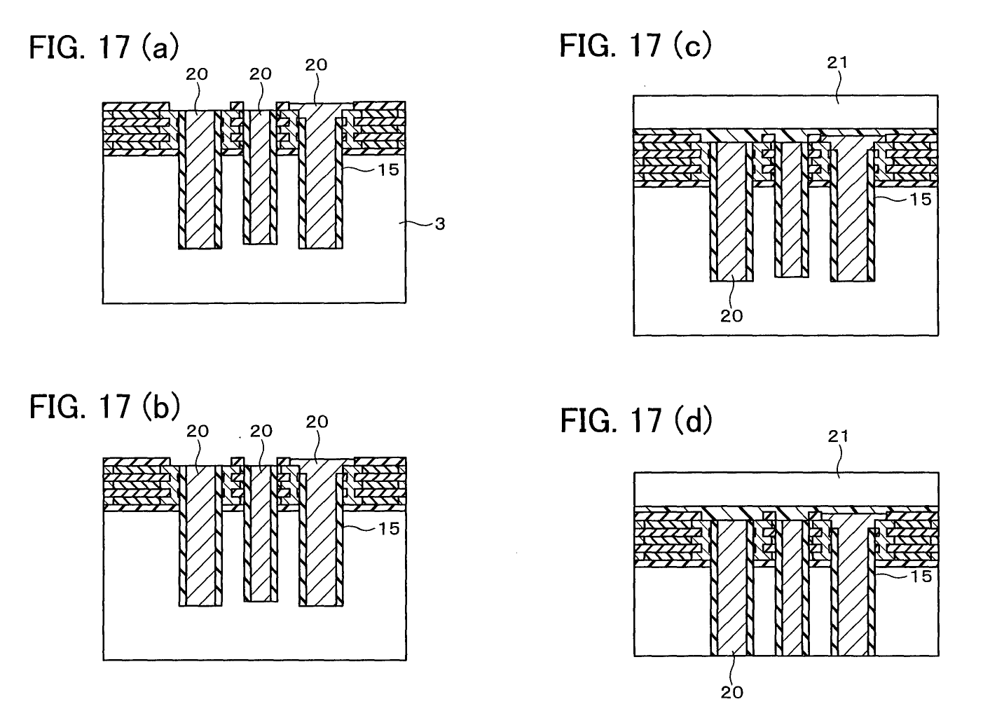

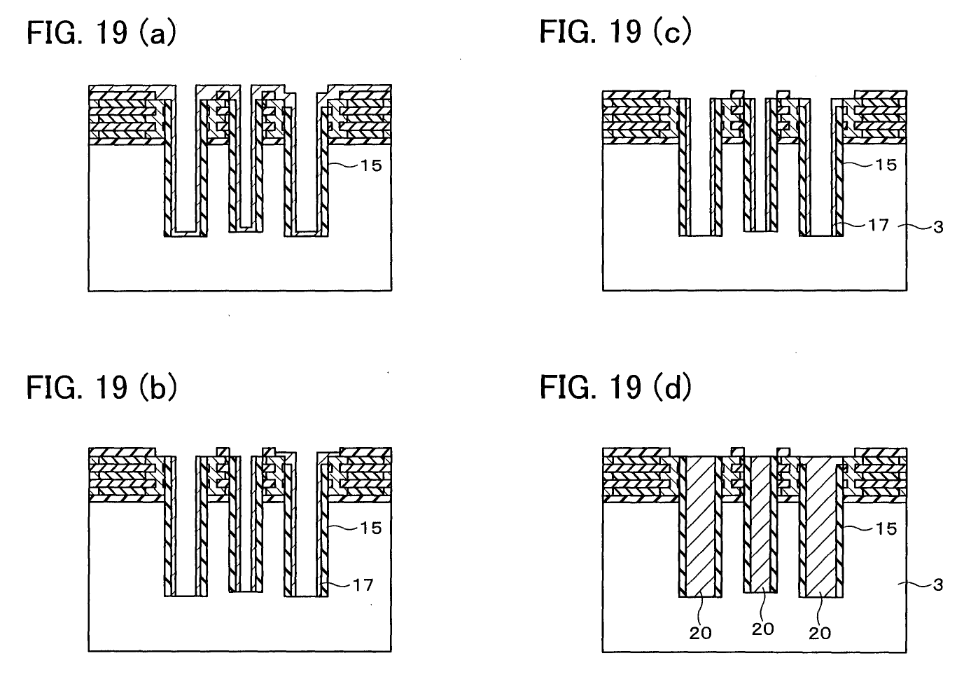

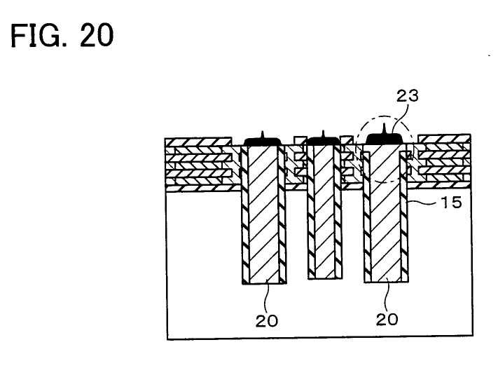

Note that, in the above description, as shown in FIG. 16(a) through FIG. 17(b), in the formation of the contact through electrode 11 on the right side, after the formation of rearranged interconnect pattern 5c, the bump 23 was formed. However, the present invention is not necessarily limited to this. For example, as shown in FIG. 19(a) through FIG. 20, the bump 23 may be formed without forming the rearranged interconnect pattern 5c. This eliminates rearrangement of the interconnect.

Thus, in the chip-stack semiconductor device 40 of the present embodiment, the through electrode 1 is further provided in the region outside of the electrode pad 2. Therefore, the through electrodes 1 are provided in the region inside of the electrode pad 2 and further in the region outside of the electrode pad 2, which is adaptable to the multiplayer chip-stack semiconductor device 40.

Further, in the chip-stack semiconductor device 40 of the present embodiment, since the through electrodes 1 of the semiconductor chips 10 are connected to each other via the bumps 23 so that the semiconductor chips 10 are stacked on top of each other, it is possible to easily perform the stacking step.

Still further, in a manufacturing method of the chip-stack semiconductor device 40 of the present embodiment, the semiconductor chip manufacturing step includes the step of further forming the through electrode 1 in the region outside of the electrode pad 2. Therefore, the through electrodes 1 are formed in the region inside of the electrode pad 2, and further, the through electrodes 1 are further formed in the region outside of the electrode pad 2, thereby easily manufacturing the chip-stack semiconductor device 40 which is adaptable to the multi-layer chip-stack semiconductor device 40.

[Embodiment 3]

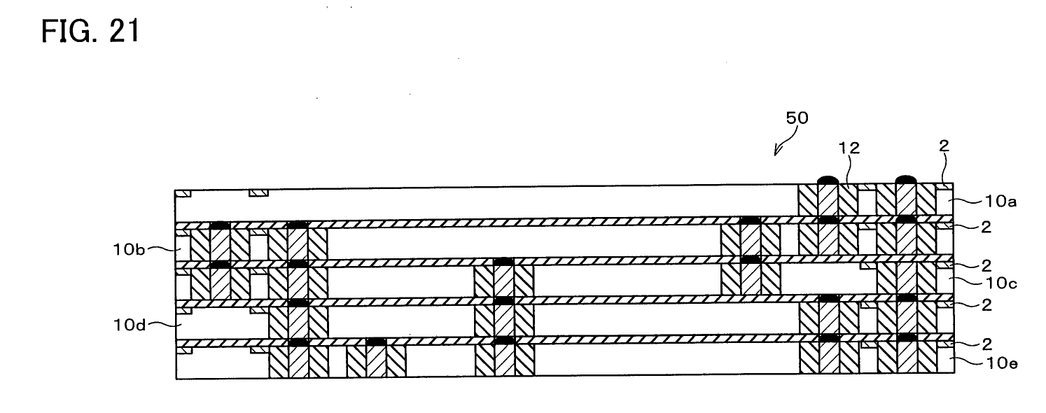

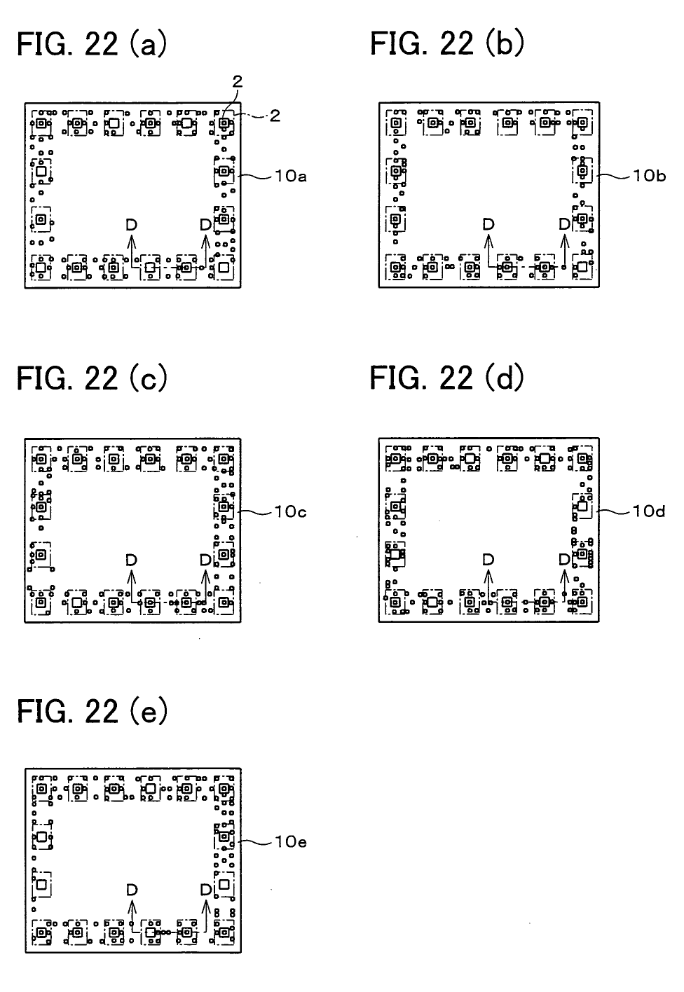

The following will describe still another embodiment of the present invention with reference to FIG. 21 and FIG. 22. For convenience, members of the present embodiment that have the same arrangement and function as members of embodiments 1 and 2, and that are mentioned in those embodiments are indicated by the same reference numerals and description thereof is omitted.

In the existing semiconductor chip 10 of the type in which the external lead electrode pads 2 are aligned along the periphery of the semiconductor chip 10, the electrode pad 2 is generally too large in size. This causes an insufficient space, resulting in a difficulty of maintaining a space for the formation of the non-contact through electrodes 12.

In view of this, in the chip-stack semiconductor device 50 of the present embodiment, as shown in FIG. 21 and FIG. 22(a) through FIG. 22(e), a mask is changed to reduce the region of the electrode pad 2 in the interconnect pattern 5 of the semiconductor chip 10 so that a finished size of the electrode pad 2 is reduced.

That is, the size of the electrode pad 2 in the existing semiconductor chip 10, as indicated by a dashed line in FIG. 22(a) through FIG. 22(e), is 70 μm per side. In the present embodiment, a finished size of the electrode pad 2 is changed to, for example, 15 μm per side.

In a space made available by the change in size of the electrode pad 2, a pattern of the non-contact through electrode through hole 12a for the non-contact through electrode 12 as well as the normal through hole 1a are formed using a reduction projection aligner, after application of the resist 14, as in the embodiments 1 and 2.

At this moment, the interlayer insulating films 6, which exist all under the pattern for the formation of the non-contact through electrode through hole 12, are etched by the same etching method as that in embodiments 1 and 2. Therefore, an etching rate of the interlayer insulating film 6 is extremely slow in the step of metal etching, as described in embodiment 1.

Further, although a drawing is omitted, a residual insulating film in the interlayer film 13, which remains in the final step of etching, is etched. At this moment, the silicon (Si) substrate 3 is over-etched about 1 micrometer in depth. However, this value is not a problem because it is followed by etching the silicon (Si) substrate 3 down to 50 μm to 70 μm in depth.

The steps after etching are the same as those in embodiments 1 and 2.

Thus, in the chip-stack semiconductor device 50 of the present embodiment, the semiconductor chip manufacturing step includes, before the step of forming the through hole 1a, the step of forming the electrode pad 2 derived from the device region 4. In the step of forming the electrode pad 2, the electrode pad 2 is formed with its space saved by changing the mask, and the semiconductor chip manufacturing step further includes the step of forming the through electrode 1 in the region made available by the formation of the electrode pad 2 with its space saved.

Therefore, the large-sized electrode pad 2 conventionally existed. However, the electrode pad 2 formed with its size reduced enables the through electrode 1 to be further formed in a space generated at the place where the electrode pad 2 is supposed to exist.

[Embodiment 4]

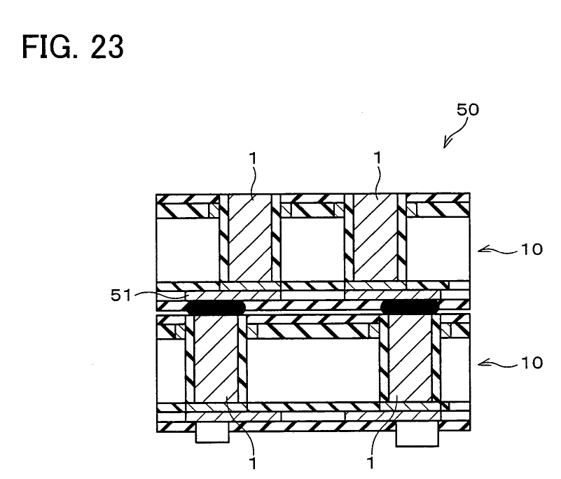

The following will describe yet another embodiment of the present invention with reference to FIG. 23 through FIG. 29. For convenience, members of the present embodiment that have the same arrangement and function as members of embodiments 1 through 3, and that are mentioned in those embodiments are indicated by the same reference numerals and description thereof is omitted.

In the case where a chip-stack semiconductor device is formed using multiple semiconductor chips 10, misalignment of the through holes 1a for the through electrodes 1 often occurs between the upper and lower semiconductor chips 10 due to a pattern layout. The solution to this problem is to provide a vertical interconnect on the back surface or front surface of the wafer in the present embodiment.

That is, in the chip-stack semiconductor device 50 of the present embodiment, the position of the through electrode 1 in the upper semiconductor chip 10 shown in FIG. 23 is deviated from the position of the through electrode 1 in the lower semiconductor chip 10 shown in FIG. 23. However, in this case, forming a vertical interconnect 51 on the back surface of the upper semiconductor chip 10 shown in FIG. 23 provides electrical connections between the through electrode 1 of the upper semiconductor chip 10 and the through electrode 1 of the lower semiconductor chip 10.

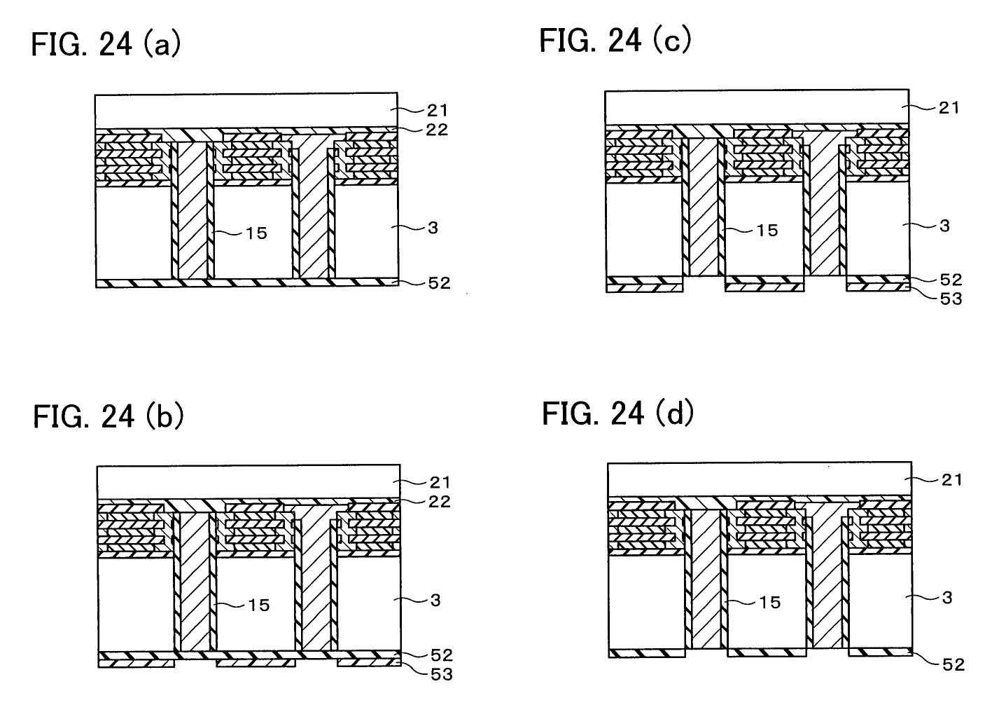

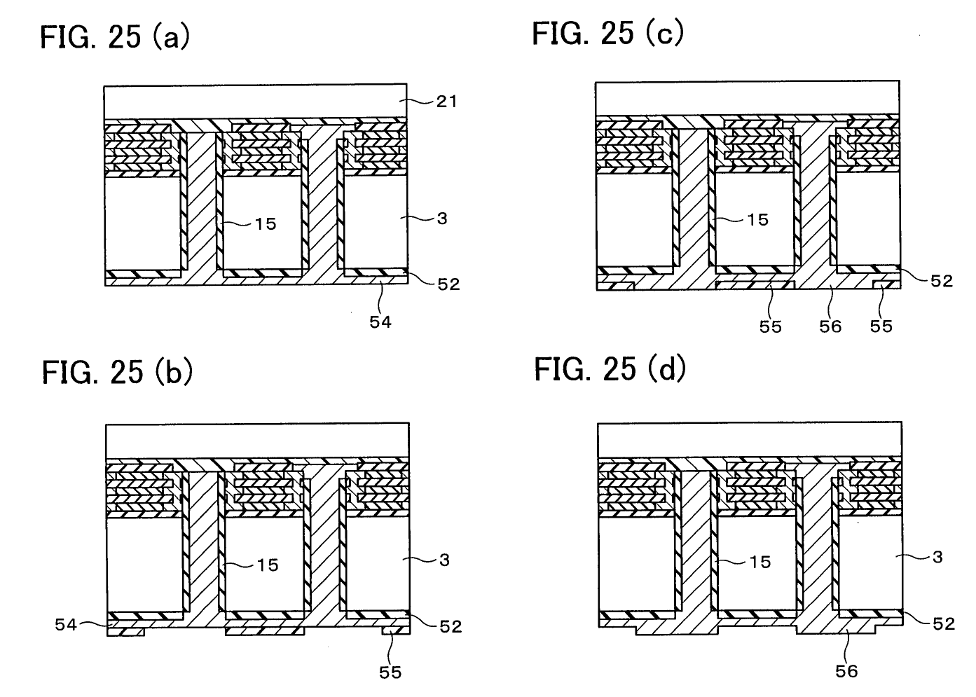

The following will describe how to form the vertical interconnect 51 with reference to FIGS. 24 and 25.

As shown in FIG. 24(a), before removing the support board 21 after the completion of polishing the back of the wafer in embodiments 1 and 2 (see FIG. 8(c)), an insulating film 52 is deposited on the back of the wafer. Then, as shown in FIG. 24(b), a resist 53 is applied thereon. Thereafter, as shown in FIG. 24(c), the insulating film 52 is etched using a reduction projection aligner.

Next, as shown in FIG. 24(d), the resist 53 is removed. Thereafter, as shown in FIG. 25(a), a barrier metal and conductive material 54 is attached in order, and another resist 55 is attached. This is carried out for the purpose of covering with the resist 55 the place where plating is unwanted at the next step of electrolytic plating, as shown in FIG. 25(b). Note that, the barrier metal refers to a barrier film provided on the boundary of the connected part between metal interconnect such as aluminum (Al), copper (Cu), and tungsten (W), contact or via hole filled with tungsten (W) plug, or via hole filled with copper (Cu) by dual damascene process, and various insulating films, semiconductor substrate made of silicon (Si) or other material, polycrystalline silicon layer, silicide layer, and other interconnect layer. The barrier film has the effect of suppressing alloy reaction in the connected part and spreading of silicon (Si) to metal interconnect, and a metal such as titanium nitride, titanium tungsten, tungsten nitride, or tantalum nitride is often used for the barrier film.

Further, the conductive material 54 is, for example, an electricity-conducting material such as aluminum (Al), copper (Cu), and tungsten (W).

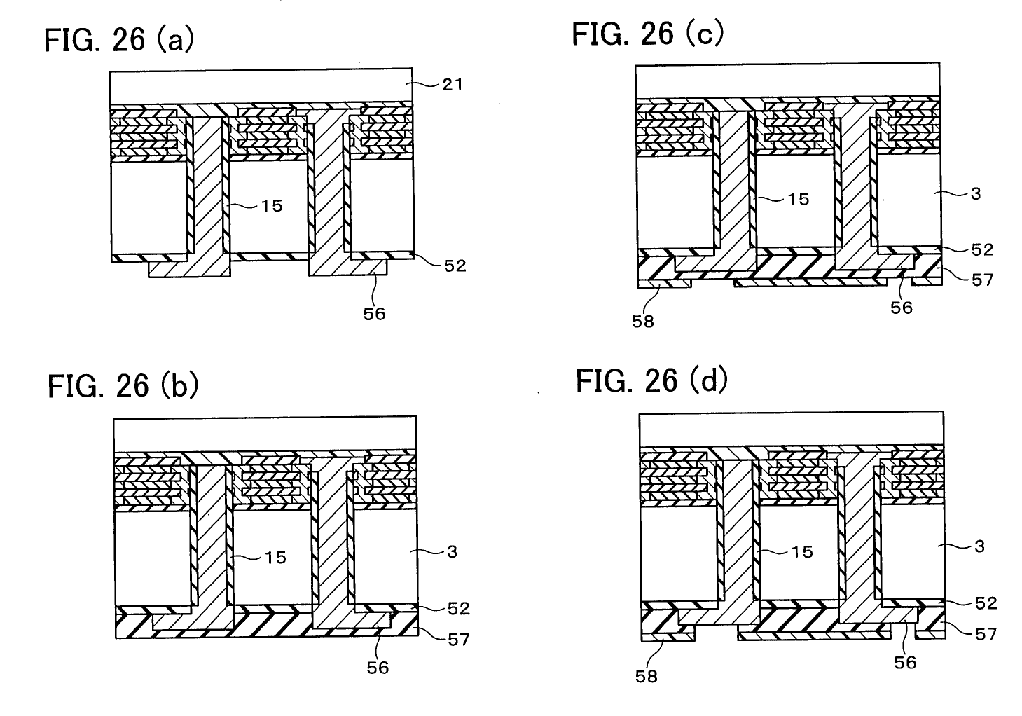

Next, as shown in FIG. 25(c) and FIG. 25(d), after a conductor 56 is electroplated, the resist 55 is removed. Further, the plating is removed, as shown in FIG. 26(a), by a chemical where it is not necessary, and a protection film 57 is attached thereon as shown in FIG. 26(b).

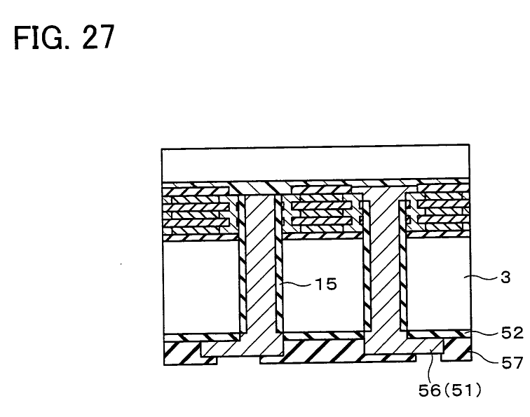

Subsequently, as shown in FIG. 26(c), a resist 58 is patterned. Then, as shown in FIG. 26(d), openings are made by etched. Finally, as shown in FIG. 27, the resist 58 is removed, which completes the formation of the vertical interconnect 51.

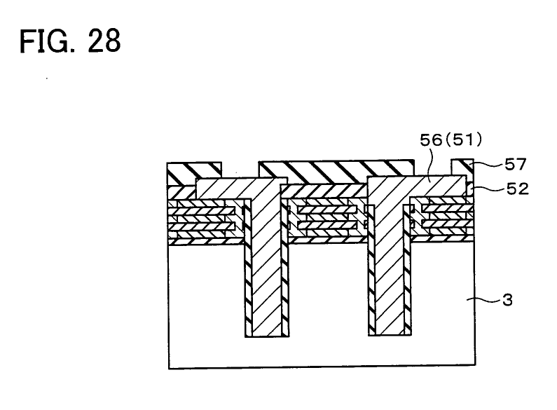

Note that, in the above example, the vertical interconnect 51 was formed on the back of the semiconductor chip 10. However, as shown in FIG. 28, before the step of polishing the back of the wafer, the vertical interconnect 51 may be formed on the front surface of the semiconductor chip 10.

Further, in the present embodiment, the conductor 56 was provided by electrolytic plating. However, the present invention is not necessarily limited to this. For example, the conductor 56 may be provided by electroless plating. This electroless plating is a process in which neither electrodes nor external power supply are needed for electroplating. In this electroless plating step, a conductor acts as a catalyst and changes into plating.

In this case, as shown in FIG. 24(a) through FIG. 24(d), before removing the support board 21 after the completion of polishing the back of the wafer, the insulating film 52 is deposited on the back of the wafer. Then, after the resist 53 is applied, the insulating film 52 is etched using a reduction projection aligner.

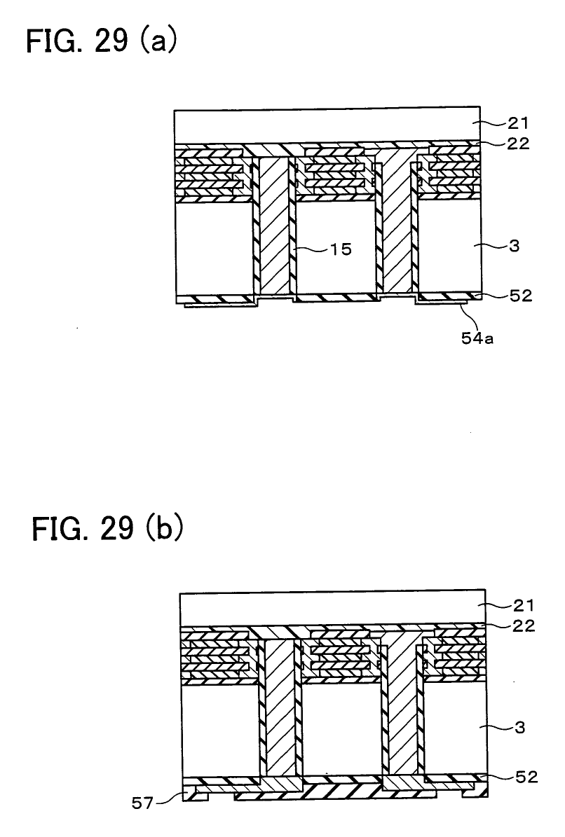

Next, as shown in FIG. 29(a), a barrier metal 54a is sputtered, and a resist not shown is applied thereon. Thereafter, the parts where electroless plating is necessary etching are left by etching.

Thereafter, the same steps shown in FIG. 26(b) through 26(d) and FIG. 27 are carried out. Finally, as shown in FIG. 29(b), the protection film 57 is attached thereon to complete.

As described above, in the chip-stack semiconductor device of the present invention, the electrode pads are provided along the periphery of the semiconductor chip so as to surround the device region.

According to the above invention, the device region does not interfere with forming the through electrodes.

Further, the chip-stack semiconductor device of the present invention is such that in the above-described chip-stack semiconductor device, at least one type of the through electrodes is contact through electrodes electrically connected to the electrode pad.

According to the above invention, it is possible to form the contact through electrode which is connected to a typical device region.

Still further, the chip-stack semiconductor device of the present invention is such that in the above-described chip-stack semiconductor device, at least one type of the through electrodes is non-contact through electrodes not electrically connected to the electrode pad.

According to the above invention, the non-contact through electrodes not connected to the device region are provided merely for providing electrical paths though the semiconductor chips as the through electrodes. Therefore, the heat generated in the semiconductor chip can be discharged outside via the non-contact through electrodes or can be guided to the semiconductor chip in the lower layer in such a manner that the non-contact through electrodes are connected to the contact through electrodes of the semiconductor chip in the upper layer.

Yet further, the chip-stack semiconductor device of the present invention is such that in the above-described chip-stack semiconductor device, a through electrode is further provided in the region outside of the electrode pad.

According to the above invention, the through electrodes are formed in the region inside of the electrode pad, and further, the through electrodes are further formed in the region outside of the electrode pad, thereby being adaptable to a multi-layer chip-stack semiconductor device.

Further, the chip-stack semiconductor device of the present invention is such that in the above-described chip-stack semiconductor device, the through electrodes in the semiconductor chips are connected to each other via bumps so that the semiconductor chips are vertically stacked on top of each other.

According to the above invention, since the through electrodes in the semiconductor chips are connected to each other via the bumps so that the semiconductor chips are stacked on top of each other, it is possible to easily perform the stacking step.

Further, the manufacturing method of the chip-stack semiconductor device of the present invention is such that in the above-described manufacturing method of the chip-stack semiconductor device, the semiconductor chip manufacturing step includes, between the step of forming an insulating film on the inside wall of a groove and the step of filling the groove with a conductive material, the step of removing the insulating film formed on the inside wall of the groove in the same layer as the electrode pad.

According to the above invention, it is possible to easily form the non-contact through electrode.

Further, the manufacturing method of the chip-stack semiconductor device of the present invention is such that in the above-described manufacturing method of the chip-stack semiconductor device, the semiconductor chip manufacturing step includes the step of further forming a through electrode in the region outside of the electrode pad.

According to the above invention, the through electrodes are formed in the region inside of the electrode pad, and further, the through electrodes are further formed in the region outside of the electrode pad, thereby easily manufacturing a chip-stack semiconductor device which is adaptable to a multiplayer chip-stack semiconductor device.

Still further, the manufacturing method of the chip-stack semiconductor device of the present invention is such that in the above-described manufacturing method of the chip-stack semiconductor device, the semiconductor chip manufacturing step includes step of forming the electrode pad derived from the device region before the step of forming the groove, in the step of forming the electrode pad, the electrode pad is formed with its space saved by changing the mask, and the semiconductor chip manufacturing step further includes step of forming a through electrode in a region made available by the formation of the electrode pad with its space saved.

According to the above invention, the large-sized electrode pad conventionally existed. However, the electrode pad formed with its size reduced enables further forming the through electrode in a space generated at the place where the electrode pad is supposed to exist.

Yet further, the manufacturing method of the chip-stack semiconductor device of the present invention is such that in the above-described manufacturing method of the chip-stack semiconductor device, in the step of forming the groove being made through the electrode pad and having a predetermined depth in the semiconductor chip of the semiconductor chip manufacturing step, a plurality of the groove is formed in a region inside of the electrode pad.

According to the above invention, it is possible to form multiple contact through electrodes and non-contact through electrodes in the region inside of one electrode pad.

The invention being thus described, it will be obvious that the same may be varied in many ways. Such variations are not to be regarded as a departure from the spirit and scope of the invention, and all such modifications as would be obvious to one skilled in the art intended to be included within the scope of the following claims.

What is claimed is:

1. A chip-stack semiconductor device, comprising multiple semiconductor chips vertically stacked on top of each other,
wherein:
each of the semiconductor chips includes multiple through electrodes connected to each other in regions inside of electrode pads derived from a device region, each of the through electrodes linking a front surface to a back surface of the semiconductor chip.

2. The chip-stack semiconductor device as set forth in claim 1, wherein the electrode pads are provided along a periphery of the semiconductor chip so as to surround the device region.

3. The chip-stack semiconductor device as set forth in claim 1, wherein at least one type of the through electrodes is contact through electrodes electrically connected to the electrode pad.

4. The chip-stack semiconductor device as set forth in claim 2, wherein at least one type of the through electrodes is contact through electrodes electrically connected to the electrode pad.

5. The chip-stack semiconductor device as set forth in claim 1, wherein at least one type of the through electrodes is non-contact through electrodes not electrically connected to the electrode pad.

6. The chip-stack semiconductor device as set forth in claim 2, wherein at least one type of the through electrodes is non-contact through electrodes not electrically connected to the electrode pad.

7. The chip-stack semiconductor device as set forth in claim 1, wherein a through electrode is further provided in regions outside of the electrode pad.

8. The chip-stack semiconductor device as set forth in claim 2, wherein a through electrode is further provided in regions outside of the electrode pad.

9. The chip-stack semiconductor device as set forth in claim 1, wherein the through electrodes in the semiconductor chips are connected to each other via bumps so that the semiconductor chips are vertically stacked on top of each other.

10. The chip-stack semiconductor device as set forth in claim 2, wherein the through electrodes in the semiconductor chips are connected to each other via bumps so that the semiconductor chips are vertically stacked on top of each other.

11. A manufacturing method of a chip-stack semiconductor device, comprising:
semiconductor chip manufacturing step of forming semiconductor chips; and
semiconductor chip stacking step of stacking a plurality of the multiple semiconductor chip,
the semiconductor chip manufacturing step including the steps of:
(a) using a mask having an opening with a predetermined shape in a region inside of an electrode pad derived from a device region, forming a groove being made through the electrode pad and having a predetermined depth in the semiconductor chip;
(b) forming an insulating film on an inside wall of the groove;
(c) filling the groove with a conductive material; and
(d) forming the through electrode made of the conductive material linking a front surface to a back surface of the semiconductor chip by removing a back surface of the semiconductor chip partially in a thickness direction to expose the conductive material,
the steps (a)-(d) being carried out in this order.

12. The manufacturing method as set forth in claim 11, wherein the semiconductor chip manufacturing step includes step of removing the insulating film formed on the inside wall of the groove in the same layer as the electrode pad between the steps (b) and (c).

13. The manufacturing method as set forth in claim 11, wherein the semiconductor chip manufacturing step includes step of further forming a through electrode in regions outside of the electrode pad.

14. The manufacturing method as set forth in claim 12, wherein the semiconductor chip manufacturing step includes step of further forming a through electrode in regions outside of the electrode pad.

15. The manufacturing method as set forth in claim 11, wherein the semiconductor chip manufacturing step includes step of forming the electrode pad derived from the device region before the step (a),
in the step of forming the electrode pad, the electrode pad is formed with its space saved by changing the mask, and
the semiconductor chip manufacturing step further includes step of forming a through electrode in a region made available by the formation of the electrode pad with its space saved.

16. The manufacturing method as set forth in claim 12, wherein the semiconductor chip manufacturing step includes step of forming the electrode pad derived from the device region before the step (a),
in the step of forming the electrode pad, the electrode pad is formed with its space saved by changing the mask, and
the semiconductor chip manufacturing step further includes step of forming a through electrode in a region made available by the formation of the electrode pad with its space saved.

17. The manufacturing method as set forth in claim 11, wherein in the step (a) of the semiconductor chip manufacturing step, a plurality of the groove is formed in a region inside of the electrode pad.

18. The manufacturing method as set forth in claim 12, wherein in the step (a) of the semiconductor chip manufacturing step, a plurality of the groove is formed in a region inside of the electrode pad.
